(19) United States
(12) Patent Application Publication
(10) Pub. No.: US 2026/0247734 A1
(43) Pub. Date: Aug. 20, 2026

(54) LIGHT DETECTION DEVICE AND ELECTRONIC DEVICE

(71) Applicant: SONY SEMICONDUCTOR SOLUTIONS CORPORATION, KANAGAWA (JP)

(72) Inventors: SHINICHI IMAI, KANAGAWA (JP); SHIN NONAKA, KANAGAWA (JP); TADAMASA SHIOYAMA, KANAGAWA (JP)

(21) Appl. No.: 19/162,602

(22) PCT Filed: Mar. 11, 2024
(86) PCT No.: PCT/JP2024/009442

§ 371 Date: Sep. 5, 2025

(30) Foreign Application Priority Data
Mar. 24, 2023 (JP) 2023-048849

(51) Int. Cl. H10F 39/00; H10F 39/18

(52) U.S. Cl. CPC H10F 39/811; H10F 39/18; H10F 39/807

(57) ABSTRACT

Provided is a light detection device that copes with refinement. The light detection device includes: a first semiconductor layer that includes one surface as an element formation surface and the other surface as a light incident surface and includes a plurality of cell regions aligned in a matrix shape in a row direction and a column direction in planar view; a trench separation wall that sections the cell regions; and an insulating region that is provided at an end portion of the trench separation wall near the element formation surface, has a dimension in a width direction that is larger than a dimension of the trench separation wall in the width direction in planar view, and is made of an insulating material, in which a photoelectric conversion unit is configured in each of the cell regions, and each of the cell regions includes a first semiconductor region provided on a surface of the insulating region on the side opposite to a surface on the side of the trench separation wall.

### TECHNICAL FIELD

The present technology (a technology according to the present disclosure) relates to a light detection device and an electronic device, and particularly to a light detection device and an electronic device that cope with refinement.

### BACKGROUND ART

In recent years, further refinement of pixels has been desired. With refinement of pixels, trench separation may be used as a separation structure to section semiconductor regions (PTL 1, for example).

### CITATION LIST

### Patent Literature

### [PTL 1]

Japanese Patent Application Publication No. 2022-55356

### SUMMARY

### Technical Problem

It has not always been possible to easily realize further refinement of pixels.

An object of the present technology is to provide a light detection device and an electronic device that cope with refinement.

### Solution to Problem

A light detection device according to one aspect of the present technology includes: a first semiconductor layer that has one surface as an element formation surface and the other surface as a light incident surface and includes a plurality of cell regions aligned in a matrix shape in a row direction and a column direction in planar view; a trench separation wall that sections the cell regions; and an insulating region that is provided at an end portion of the trench separation wall near the element formation surface, has a dimension in a width direction that is larger than a dimension of the trench separation wall in the width direction in planar view, and is made of an insulating material, in which a photoelectric conversion unit is configured in each of the cell regions, and each of the cell regions includes a first semiconductor region provided on a surface of the insulating region on a side opposite to a surface on a side of the trench separation wall.

An electronic device according to one aspect of the present technology includes the above-described light detection device and an optical system that forms an image of image light from a subject on the above-described light detection device.

### BRIEF DESCRIPTION OF DRAWINGS

FIG. 1 is a chip layout diagram illustrating a configuration example of a light detection device according to a first embodiment of the present technology.

FIG. 2 is a block diagram illustrating a configuration example of the light detection device according to the first embodiment of the present technology.

FIG. 3 is an equivalent circuit diagram of a pixel in the light detection device according to the first embodiment of the present technology.

FIG. 4A is a longitudinal sectional view illustrating a sectional configuration of a pixel included in the light detection device according to the first embodiment of the present technology.

FIG. 4B is a horizontal sectional view illustrating a sectional configuration taken along the cut line B-B in FIG. 4A.

FIG. 4C is a horizontal sectional view illustrating a sectional configuration taken along the cut line C-C in FIG. 4A.

FIG. 4D is an explanatory diagram illustrating a positional relationship of an electrode, a charge accumulation region, a contact region, a first semiconductor region, and a second semiconductor region on the side of a first surface of a first semiconductor layer according to the first embodiment.

FIG. 4E is a partial enlarged view illustrating a part of FIG. 4D in an enlarged manner.

FIG. 4F is a longitudinal sectional view illustrating a part of a sectional configuration taken along a plane along the cut line A-A in FIG. 4D in an enlarged manner.

FIG. 4G is a longitudinal sectional view illustrating a sectional configuration

FIG. 4H is a plan view when a trunk portion according to the first embodiment is seen in planar view.

FIG. 5A is a process sectional view illustrating a method of manufacturing the light detection device according to the first embodiment of the present technology.

FIG. 5B is a process sectional view following FIG. 5A.

FIG. 5C is a process sectional view following FIG. 5B.

FIG. 5D is a process sectional view following FIG. 5C.

FIG. 5E is a process sectional view following FIG. 5D.

FIG. 5F is a process sectional view following FIG. 5E.

FIG. 5G is a process sectional view following FIG. 5F.

FIG. 5H is a process sectional view following FIG. 5G.

FIG. 5I is a process sectional view following FIG. 5H.

FIG. 5J is a process sectional view following FIG. 5I.

FIG. 6 is a longitudinal sectional view illustrating a sectional configuration of an electrode and a charge accumulation region included in a light detection device according to a comparative example.

FIG. 7A is an explanatory diagram illustrating a positional relationship of an electrode, a charge accumulation region, a first semiconductor region, and a second semiconductor region on the side of a first surface of a first semiconductor layer included in a light detection device according to a first modification example of the first embodiment of the present technology.

FIG. 7B is a longitudinal sectional view illustrating a sectional configuration taken along the cut line E-E in FIG. 7A.

FIG. 8A is a process sectional view illustrating a method of manufacturing a light detection device according to the first modification example of the first embodiment of the present technology.

FIG. 9A a is a plan view illustrating a planar shape of an opening of a resist pattern used in the process illustrated in FIG. 8B.

FIG. 9B is an explanatory diagram illustrating a state where silicon is epitaxially grown only at a corner of a cell region in the light detection device according to the first modification example of the first embodiment of the present technology.

FIG. 10 is an explanatory diagram illustrating a gate electrode and an electrode included in a light detection device 1 according to a second modification example of the first embodiment in planar view.

FIG. 11 is an explanatory diagram illustrating a gate electrode and an electrode included in a light detection device 1 according to a third modification example of the first embodiment in planar view.

FIG. 12 is an explanatory diagram illustrating a gate electrode and an electrode included in a light detection device 1 according to a fourth modification example of the first embodiment in planar view.

FIG. 13 is an explanatory diagram illustrating an electrode included in a light detection device 1 according to a fifth modification example of the first embodiment in planar view.

FIG. 14A is a longitudinal sectional view illustrating a sectional configuration of an electrode, a charge accumulation region, and an insulating region taken along a plane along a cut line crossing a trunk portion in a light detection device according to a second embodiment of the present technology.

FIG. 14B is an explanatory diagram illustrating a positional relationship and a dimensional relationship between the charge accumulation region and the electrode in planar view in the light detection device according to the second embodiment of the present technology.

FIG. 15A is a process sectional view illustrating a method of manufacturing the light detection device according to the second embodiment of the present technology.

FIG. 15B is a process sectional view following FIG. 15A. FIG. 15C is a process sectional vie following FIG. 15B.

FIG. 15D is a process sectional view following FIG. 15C.

FIG. 15E IS A PROCESS SECTIONAL VIEW FOLLOWING FIG. 15D.

FIG. 16 is an explanatory diagram illustrating a positional relationship of a gate electrode and a charge accumulation region included in a light detection device according to a comparative example in planar view.

FIG. 17 is an explanatory diagram illustrating a positional relationship of the gate electrode and the charge accumulation region included in the light detection device according to the second embodiment of the present technology in planar view.

FIG. 18A is an explanatory diagram illustrating a positional relationship of a gate electrode and a charge accumulation region included in a light detection device according to a first modification example of the second embodiment of the present technology in planar view.

FIG. 18B is an explanatory diagram illustrating the positional relationship of the gate electrode and the charge accumulation region included in the light detection device according to the first modification example of the second embodiment of the present technology in planar view.

FIG. 19A is a process sectional view illustrating a method of manufacturing a light detection device according to a second modification example of the second embodiment of the present technology.

FIG. 19B is a process sectional view following FIG. 19A.

FIG. 20A is a longitudinal sectional view illustrating a sectional configuration of a phase difference detection unit included in a light detection device according to a third embodiment of the present technology.

FIG. 20B is an explanatory diagram illustrating a positional relationship between a first semiconductor region and a first trench separation wall on the side of a first surface of the phase difference detection unit according to the third embodiment of the present technology.

FIG. 20C is a longitudinal sectional view illustrating a sectional configuration taken along the cut line G-G in FIG. 20B.

FIG. 20D is an explanatory diagram illustrating a configuration of four phase difference detection units aligned in two rows and two columns on the side of the first surface according to the third embodiment of the present technology.

FIG. 21 is a plan view illustrating a resist pattern used when a groove is formed by etching from the side of a first surface S1 by a method of manufacturing the light detection device according to the third embodiment of the present technology.

FIG. 22 illustrates the shape and the position of an insulating region, which is formed by the method of manufacturing the light detection device according to the third embodiment of the present technology, in planar view.

FIG. 23 is a longitudinal sectional view illustrating a first semiconductor region formed through epitaxial growth by the method of manufacturing the light detection device according to the third embodiment of the present technology.

FIG. 24 is a longitudinal sectional view illustrating a sectional configuration of a pixel included in a light detection device according to a comparative example.

FIG. 25A is an explanatory diagram illustrating a configuration of four phase difference detection units, which are aligned in two rows and two columns, on the side of a first surface according to a first modification example of the third embodiment of the present technology.

FIG. 25B is a longitudinal sectional view illustrating a sectional configuration taken along the cut line G-G in FIG. 25A.

FIG. 26 is a plan view illustrating a resist pattern used when etch back to remove unnecessary parts of an insulating film to obtain an insulating region is performed in a method of manufacturing the light detection device according to the first modification example of the third embodiment of the present technology.

FIG. 27 is an explanatory diagram illustrating a planar configuration of a charge accumulation region included in a light detection device according to a second modification example of the third embodiment of the present technology, on the side of a first surface S1.

FIG. 28 is an explanatory diagram illustrating a planar configuration of a charge accumulation region included in a light detection device according to a third modification example of the third embodiment of the present technology, on the side of a first surface S1.

FIG. 29 is a block diagram illustrating an example of the overall configuration of an electronic device.

### DESCRIPTION OF EMBODIMENTS

Preferred embodiments for carrying out the present technology will be described hereinafter with reference to the drawings. Note that the following embodiments describe examples of representative embodiments of the present technology, and the scope of the present technology should not be narrowly interpreted on the basis thereof.

In the following descriptions of the drawings, identical or similar elements will be given identical or similar reference numerals. However, it should be noted that the drawings are schematic, and the relationships between thicknesses and planar dimensions, the ratios of thicknesses of layers, and the like are different from the actual relationships, ratios, and the like. Therefore, specific thicknesses and dimensions should be determined in light of the following descriptions. Furthermore, it goes without saying that the drawings include elements whose dimensional relationships, ratios, and the like differ from drawing to drawing. Also, drawings suitable for describing the present technology are adopted, and there may thus be differences in configurations between the drawings.

In addition, the following embodiments illustrate examples of a device and a method for embodying the technical spirit of the present technology, and the technical spirit of the present technology is not specific to the materials, shapes, structures, arrangements, and the like of the constituent components described hereinafter. The technical spirit of the present technology can be modified in various ways within the technical scope set forth in the claims. In addition, it is to be understood that definitions of directions such as up-down in the following descriptions are merely definitions provided for the sake of brevity and are not intended to limit the technical spirit of the present disclosure. For example, it is obvious that when an object is observed after being rotated by 90 degrees, up-down is converted into and interpreted as left right, and when an object is observed after being rotated by 180 degrees, up-down is interpreted as being inverted.

The descriptions will be given in the following order.
1. First Embodiment
2. Second Embodiment
3. Third Embodiment
4. Fourth Embodiment
Example of Application to Electronic Device

### First Embodiment

A first embodiment will describe an example in which the present technology is applied to a light detection device that is a backside-illuminated Complementary Metal Oxide Semiconductor (CMOS) image sensor.

### Overall Configuration of Light Detection Device

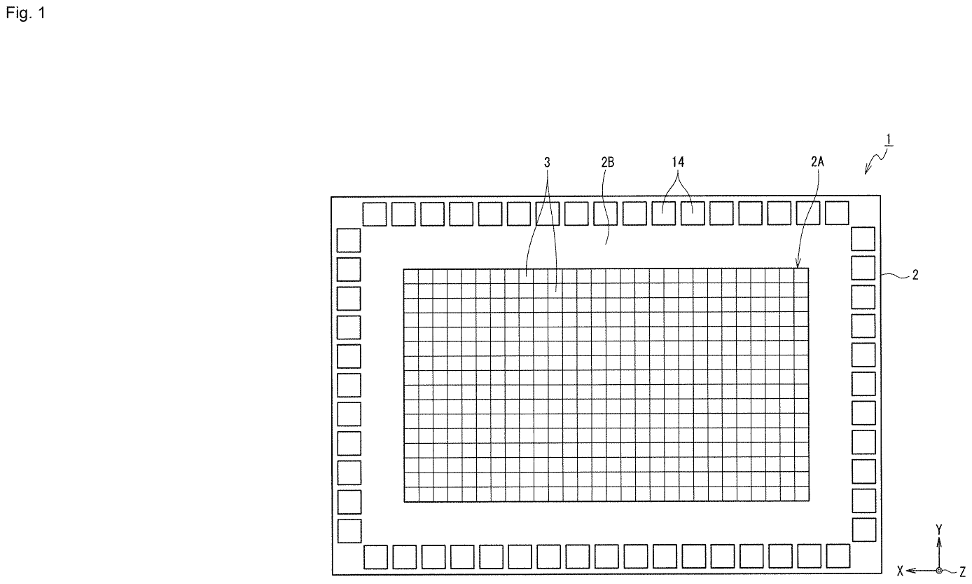

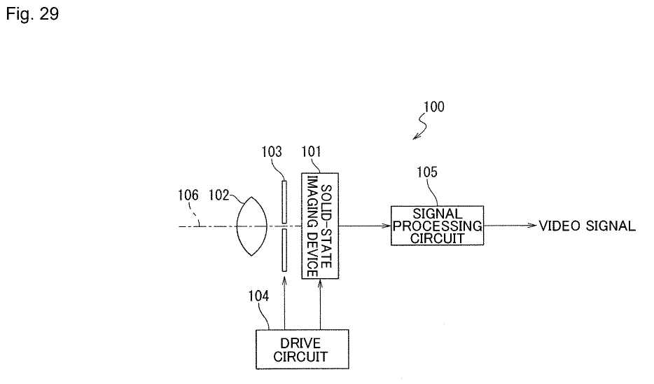

First, the entire configuration of a light detection device 1 will be described. As illustrated in FIG. 1, the light detection device 1 according to the first embodiment of the present technology is configured mainly of a semiconductor chip 2 with a rectangular two-dimensional planar shape in planar view. In other words, the light detection device 1 is mounted on the semiconductor chip 2. As illustrated in FIG. 29, the light detection device 1 takes image light (incident light 106) from a subject via an optical system (an optical lens) 102, converts the amount of light of the incident light 106 formed as an image on an imaging surface into an electric signal in units of pixels, and outputs the electric signal as a pixel signal.

As illustrated in FIG. 1, the semiconductor chip 2 with the light detection device 1 mounted thereon includes a rectangular pixel region 2A provided at the center and a peripheral region 2B provided to surround the pixel region 2A outside of the pixel region 2A in a two-dimensional plane including an X direction and a Y direction intersecting each other. The pixel region 2A is a light receiving surface that receives light collected by the optical system 102 illustrated in FIG. 29, for example. Also, a plurality of pixels 3 are arranged in a matrix shape in the two-dimensional plane including the X direction and the Y direction in the pixel region 2A. In other words, the pixels 3 are repeatedly arranged in each of the X direction (a row direction, for example) and the Y direction (a column direction, for example) intersecting each other in the two-dimensional plane. Note that the X direction and the Y direction perpendicularly intersect each other as an example in the present embodiment. In addition, the direction perpendicularly intersecting both the X direction and the Y direction is a Z direction (a thickness direction, a stacking direction). The direction perpendicular to the Z direction is a horizontal direction.

As illustrated in FIG. 1, a plurality of bonding pads 14 are arranged in the peripheral region 2B. Each of the plurality of bonding pads 14 is aligned along each of four sides of the semiconductor chip 2 in the two-dimensional plane, for example. Each of the plurality of bonding pads 14 serves as an input/output terminal used when the semiconductor chip 2 is electrically connected to an external device.

### Logic Circuitry

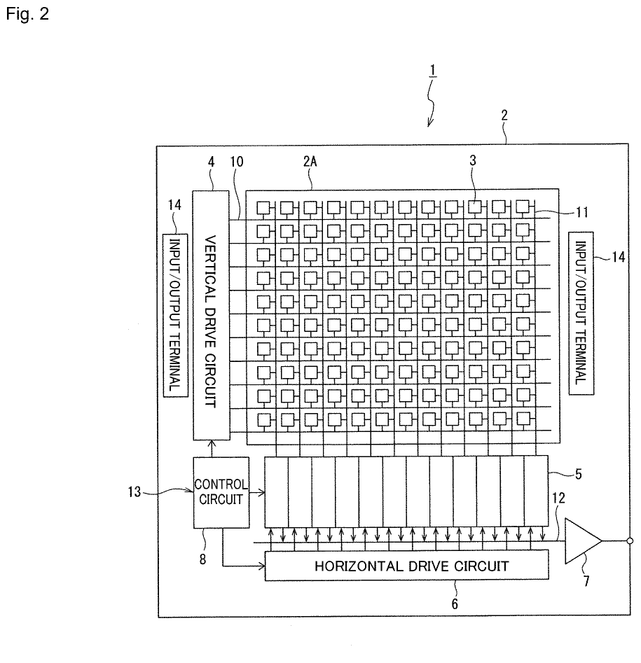

As illustrated in FIG. 2, the semiconductor chip 2 includes a logic circuit 13. The logic circuit 13 includes a vertical drive circuit 4, a column signal processing circuit 5, a horizontal drive circuit 6, an output circuit 7, a control circuit 8, and the like. The logic circuit 13 is configured as a field effect transistor by a complementary MOS (CMOS) circuit including an n-channel conductive-type metal oxide semiconductor field effect transistor (MOSFET) and a p-channel conductive-type MOSFET, for example.

For example, the vertical drive circuit 4 includes a shift register. The vertical drive circuit 4 selects a desired pixel drive line 10 in sequence, supplies a pulse for driving the pixels 3 to the selected pixel drive line 10, and drives respective pixels 3 in unit of rows. In other words, the vertical drive circuit 4 sequentially performs selective scanning of the pixels 3 of the pixel region 2A in units of rows in a vertical direction, and supplies pixel signals from the pixels 3, which are based on signal charges generated in accordance with the amount of light received by the photoelectric conversion elements of the pixels 3, to the column signal processing circuits 5 through vertical signal lines 11.

The column signal processing circuit 5, for example, is disposed in each column of the pixels 3 and performs signal processing such as noise elimination or the like for each pixel column on signals output from the pixels 3 corresponding to one row. For example, the column signal processing circuit 5 performs signal processing such as Correlated Double Sampling (CDS) for eliminating a pixel-specific fixed pattern noise, Analog Digital (AD) conversion, and the like. A horizontal selection switch (not shown) is connected and disposed between an output storage of the column signal processing circuit 5 and the horizontal signal line 12.

The horizontal drive circuit 6 is constituted by a shift register, for example. The horizontal drive circuit 6 sequentially selects each column signal processing circuit 5 by sequentially outputting a horizontal scanning pulse to the column signal processing circuit 5, and outputs a pixel signal on which signal processing has been performed from each column signal processing circuit 5 to the horizontal signal line 12.

The output circuit 7 performs signal processing on the pixel signals sequentially supplied from the respective column signal processing circuits 5 through the horizontal signal line 12, and outputs the resulting pixel signals. Examples of the signal processing which may be used include buffering, black level adjustment, column variation correction, various types of digital signal processing, and the like, for example.

The control circuit 8 generates a clock signal or a control signal as a reference for operations of the vertical drive circuit 4, the column signal processing circuit 5, the horizontal drive circuit 6, and the like based on a vertical synchronization signal, a horizontal synchronization signal, and a master clock signal. The control circuit 8 then outputs the generated clock signal or control signal to the vertical drive circuit 4, the column signal processing circuits 5, the horizontal drive circuit 6, and the like.

### Pixel

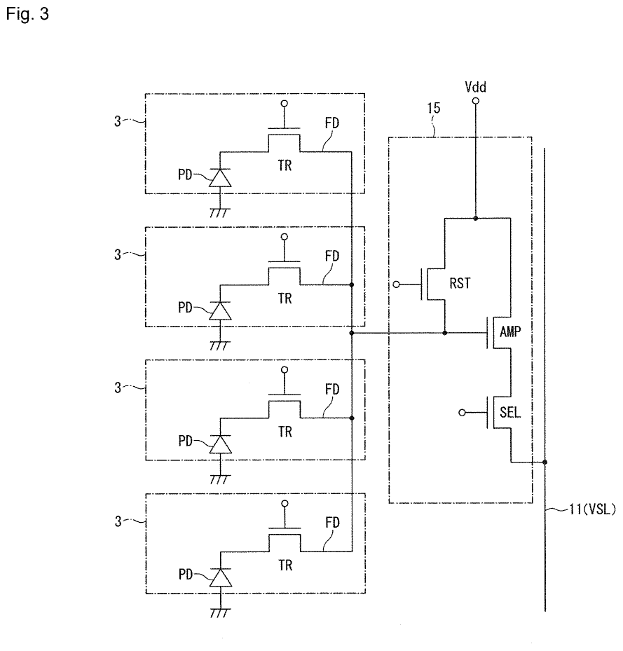

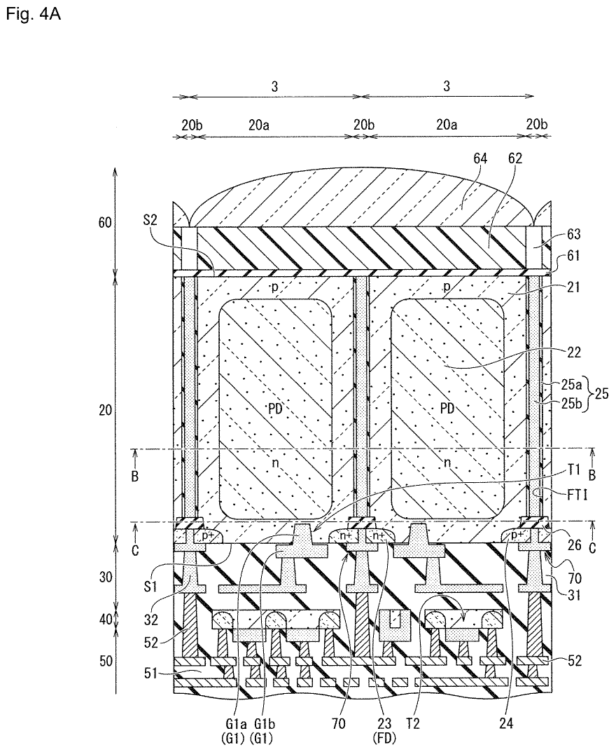

FIG. 3 is an equivalent circuit diagram illustrating a configuration example of pixels 3. In the illustrated example, the plurality of pixels 3 share one reading circuit 15. More specifically, the four pixels 3 share the one reading circuit 15.

Each of the pixels 3 includes a photoelectric conversion element PD, a transfer transistor TR that transfers a signal charge obtained by the photoelectric conversion element PD through photoelectric conversion to a charge accumulation region FD, and the charge accumulation region FD (floating diffusion). The reading circuit 15 is connected to a subsequent stage of the charge accumulation region FD.

The photoelectric conversion element PD generates a signal charge corresponding to the amount of received light. The photoelectric conversion element PD also temporarily accumulates (holds) the generated signal charge. The photoelectric conversion element PD is electrically connected to a source region of the transfer transistor TR on the cathode side and is electrically connected to a reference potential line (ground, for example) on the anode side. A photodiode is used as the photoelectric conversion element PD, for example.

A drain region of the transfer transistor TR is electrically connected to the charge accumulation region FD. A gate electrode of the transfer transistor TR is electrically connected to a transfer transistor drive line from among pixel drive lines 10 (see FIG. 2).

The charge accumulation region FD temporarily accumulates and holds the signal charge transferred from the photoelectric conversion element PD via the transfer transistor TR.

The reading circuit 15 reads the signal charge accumulated in the charge accumulation region FD and outputs a pixel signal based on signal charge. The reading circuit 15 includes, but is not limited to, an amplification transistor AMP, a selection transistor SEL, and a reset transistor RST, for example, as pixel transistors. Such a transistor (AMP, SEL, RST), for example, is configured by a MOSFET including a gate insulating film made of a silicon oxide film (an SiO₂ film), a gate electrode, and a pair of main electrode regions functioning as a source region and a drain region. In addition, such a transistor may be a metal insulator semiconductor FET (MISFET) in which a gate insulating film is formed of a silicon nitride film (an Si₃N₄ film) or a stacked film of a silicon nitride film, a silicon oxide film, and the like.

The amplification transistor AMP has a source region electrically connected to a drain region of the selection transistor SEL and a drain region electrically connected to a power supply line Vdd and a drain region of the reset transistor.

Also, the gate electrode of the amplification transistor AMP is electrically connected to the charge accumulation region FD and a source region of the reset transistor RST.

The selection transistor SEL has a source region electrically connected to a vertical signal line 11 (VSL) and a drain electrically connected to the source region of the amplification transistor AMP. Moreover, a gate electrode of the selection transistor SEL is electrically connected to a selection transistor drive line from among the pixel drive lines 10 (see FIG. 2).

The reset transistor RST has a source region electrically connected to the charge accumulation region FD and the gate electrode of the amplification transistor AMP and a drain region electrically connected to the power supply line Vdd and the drain region of the amplification transistor AMP. A gate electrode of the reset transistor RST is electrically connected to a reset transistor drive line from among the pixel drive lines 10 (see FIG. 2).

### Specific Configuration of Light Detection Device

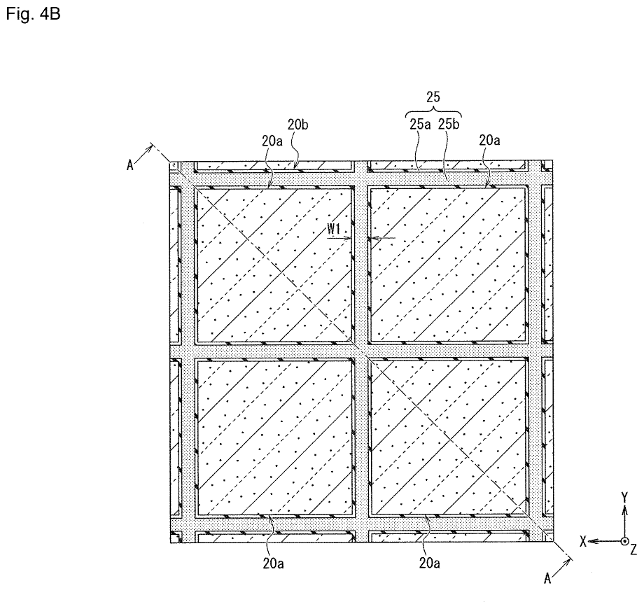

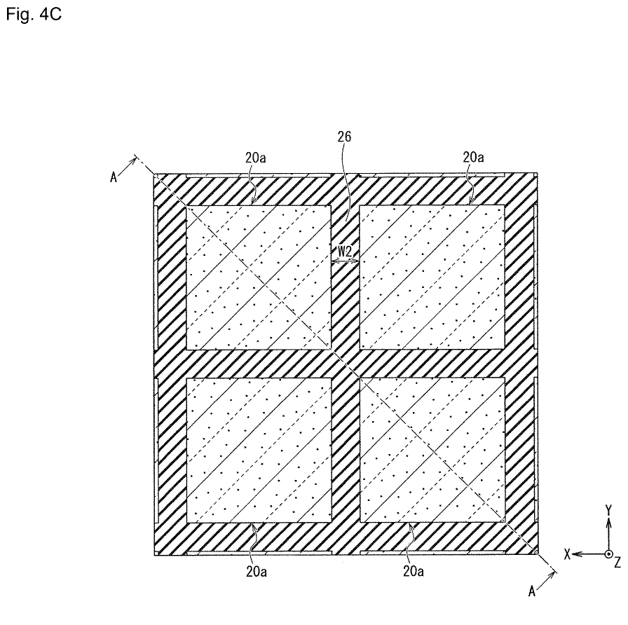

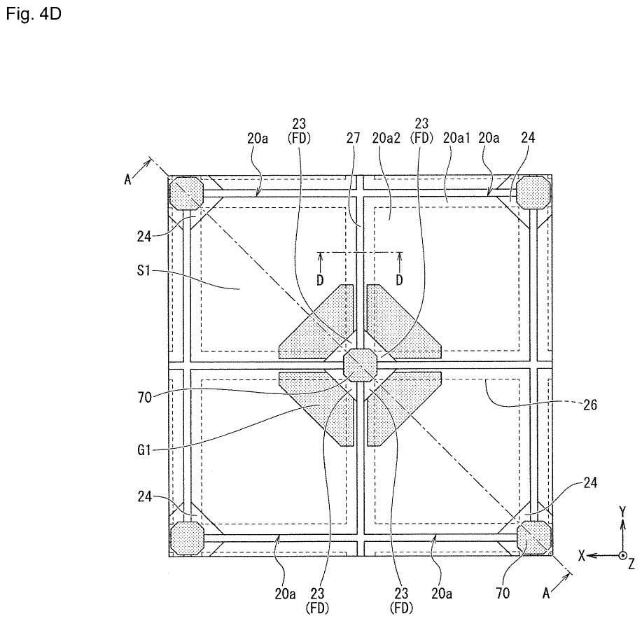

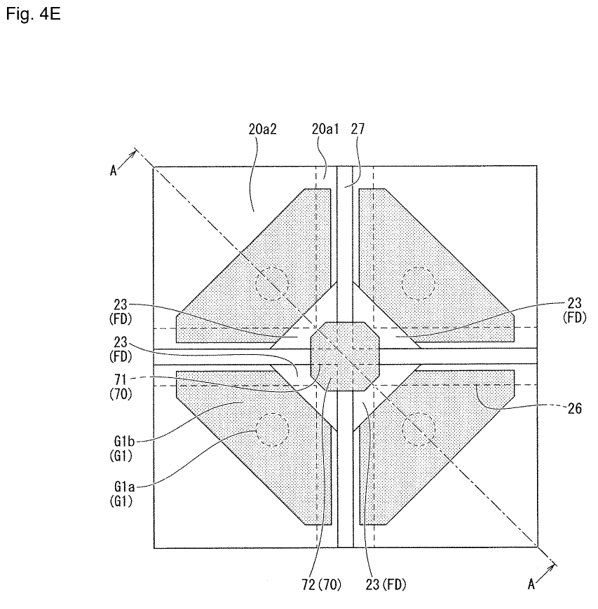

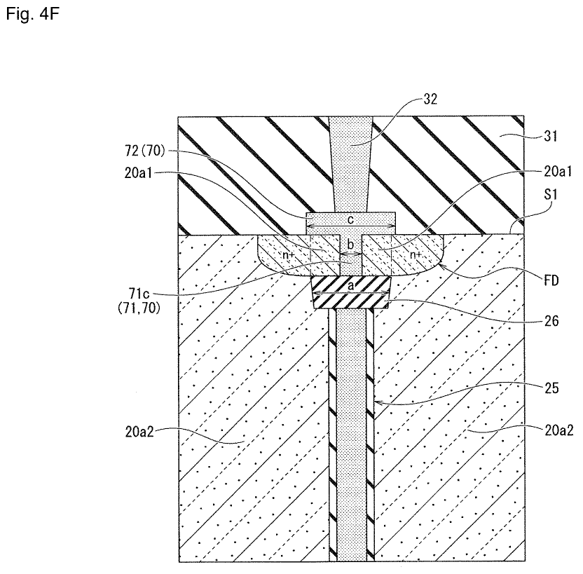

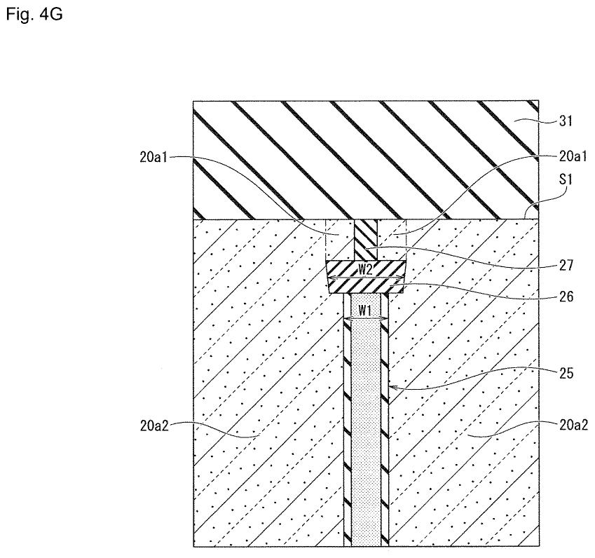

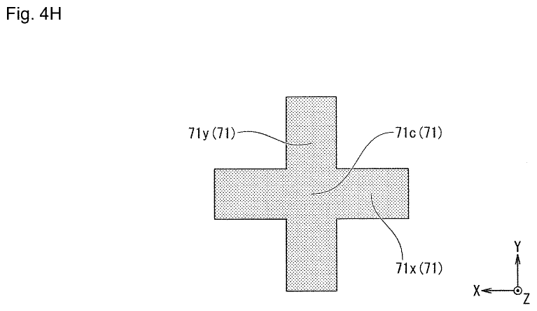

Next, a specific configuration of the light detection device 1 will be described using FIGS. 4A to 4H. Note that illustration of a barrier metal layer and a gate insulating film of a transistor may be omitted in some drawings.

### Stacked Structure of Light Detection Device

FIG. 4A is a horizontal sectional view illustrating a sectional configuration taken along the cut line A-A in FIGS. 4B and 4C and the like. As illustrated in FIG. 4A, the light detection device 1 (semiconductor chip 2) has a stacked structure in which a first semiconductor layer 20 having a first surface S1 on one side and a second surface S2 on the other side, a first wiring layer 30, a second semiconductor layer 40, a second wiring layer 50, and a third semiconductor layer, which is not illustrated, stacked in this order, for example. Also, the light detection device 1 (semiconductor chip 2) has a light incident surface-side stacked body 60 on the side of the second surface S2.

### First Semiconductor Layer

The first semiconductor layer 20 is configured of a semiconductor substrate. The first semiconductor layer 20 is configured mainly of, but is not limited to, a single-crystal silicon (Si) substrate, for example. Note that the first surface S1 may be referred to as an element formation surface or a main surface while the second surface S2 may be referred to as a light incident surface or a rear surface. A part of the first semiconductor layer 20 corresponding to the pixel region 2A is provided with a plurality of cell regions 20a that are aligned in a matrix shape along the row direction and the column direction in planar view. Each cell region 20a is provided for each pixel 3. For example, an island-shaped cell region 20a sectioned by a separation region 20b is provided for each pixel 3. Note that the number of pixels 3 is not limited to that in FIG. 4A.

A semiconductor region 21 and a semiconductor region 22 are configured in the cell region 20a. The semiconductor region 21 is a first conductive-type (p-type, for example) or intrinsic semiconductor (i-type) and will be described as a first conductive-type (p-type, for example) semiconductor in the present embodiment. The semiconductor region 22 is a second conductive-type (n-type, for example) semiconductor. Also, the photoelectric conversion element PD illustrated in FIG. 3 is configured in the cell region 20a, photoelectrically converts incident light, and generates a signal charge. Hereinafter, the semiconductor region 22 may be referred to as a photoelectric conversion unit 22.

As illustrated in FIG. 4A, a second conductive-type (n-type, for example) semiconductor region 23 and a first conductive-type (p-type, for example) semiconductor region 24 are configured in the cell region 20a. The semiconductor region 23 corresponds to the charge accumulation region FD illustrated in FIG. 3. Hereinafter, the semiconductor region 23 will be referred to as a charge accumulation region FD. The charge accumulation region FD is a diffusion region having an impurity concentration higher than that of the photoelectric conversion unit 22. The semiconductor region 24 is a contact region to which a wire for fixing the semiconductor region 21 to a reference potential is connected. Hereinafter, the semiconductor region 24 will be referred to as a contact region 24. The contact region 24 is a diffusion region having an impurity concentration higher than that of the semiconductor region 21. The charge accumulation region FD and the contact region 24 may be provided at positions near the first surface S1 in the thickness direction or may face the first surface S1. Also, the cell region 20a includes a first semiconductor region 20a1 detail separately.

As illustrated in FIG. 4A, the cell region 20a is provided with a transistor T1, for example. The transistor T1 is provided at a position near the first surface S1 of the first semiconductor layer 20. The transistor T1 is, for example, the transfer transistor TR illustrated in FIG. 3. Hereinafter, the transistor T1 will be referred to as a transfer transistor T1.

As illustrated in FIG. 4A, the separation region 20b is provided with a separation structure that sections the cell regions 20a. The separation structure may be a known structure such as an impurity separation structure, a trench separation wall, or the like. The present embodiment will be described on the assumption that the separation structure is a trench separation wall 25 illustrated in FIG. 4A. The trench separation wall 25 is a trench structure in which a groove FTI is formed in the thickness direction in the separation region 20b of the first semiconductor layer 20 and a separation material is buried in the groove FTI. The trench separation wall 25 is, for example, a full trench isolation (FTI) structure in which the separation material is buried in the groove FTI extending from the first surface S1 to the second surface S2 in the thickness direction.

The separation material may be a known material such as an insulating film or metal. In the present embodiment, the trench separation wall 25 is configured to include a polysilicon 25b and an insulating film 25a. The insulating film 25a establishes insulation between the polysilicon 25b and the semiconductor region 21. FIG. 4B is a horizontal sectional view illustrating a sectional configuration taken along the cut line B-B in FIG. 4A. As illustrated in FIG. 4B, the trench separation wall 25 includes a part extending in the row direction and the thickness direction and a part extending in the column direction and the thickness direction. Also, the part extending in the row direction and the thickness direction and the part extending in the column direction and the thickness direction intersect each other. The part where the part extending in the row direction and the thickness direction and the part extending in the column direction and the thickness direction intersect each other will be referred to as an intersection region. In the example illustrated in FIG. 4B, the trench separation wall 25 is provided in a grid shape in the row direction and the column direction in planar view. The dimension of the trench separation wall 25 in the width direction is W1.

As illustrated in FIG. 4D, each charge accumulation region FD is provided at a corner of the cell region 20a in planar view, for example, although the charge accumulation region FD is not limited thereto. More specifically, the charge accumulation regions FD are provided at mutually facing corners of four cell regions 20a in two rows and two columns sharing one reading circuit 15 in planar view. Also, each contact region 24 is provided at a corner of each cell region 20a in planar view, for example, although the contact region 24 is not limited thereto. More specifically, the contact region 24 is provided at a corner different from the corner where the charge accumulation region FD is provided, from among the corners of the cell region 20a. The contact regions 24 are provided at mutually facing corners of the four cell regions 20a in two rows and two columns in planar view.

### Insulating Region

As illustrated in FIG. 4A, an end portion of the trench separation wall 25 near the first surface S1 is provided with an insulating region 26 made of an insulating material. One surface (the surface near the second surface S2) of the insulating region 26 is in contact with the end portion of the trench separation wall 25 near the first surface S1. FIG. 4C is a horizontal sectional view illustrating a sectional configuration taken along the cut line C-C in FIG. 4A. As illustrated in FIG. 4C, the insulating region 26 extends in the row direction and the column direction to section the cell regions 20a in planar view. The insulating region 26 is provided along the trench separation wall 25 and overlaps the trench separation wall 25 in planar view. More specifically, the entire trench separation wall 25 overlaps the insulating region 26 in planar view. Moreover, the insulating region 26 is provided over the entire location where the trench separation wall 25 is provided in planar view. The dimension of the insulating region 26 in the width direction is W2, which is greater than the dimension W1 of the trench separation wall 25 in the width direction (W2>W1). Examples of the insulating material constituting the insulating region 26 include, but are not limited to, materials such as silicon oxide (SiO₂).

FIG. 4G is a longitudinal sectional view illustrating a sectional configuration taken along the cut line D-D in FIG. 4D. As illustrated in FIGS. 4D and 4G, a surface of the insulating region 26 near the first surface S1 is provided with a narrow-width insulating region 27 extending in the row direction and the column direction to section the cell regions 20a.

FIG. 4F is a longitudinal sectional view illustrating a part of a sectional configuration taken along the plane along the cut line A-A in FIG. 4D in an enlarged manner. As illustrated in FIG. 4F, the narrow-width insulating region 27 is removed and an electrode 70 is provided at the position where the charge accumulation region FD is provided. Since a similar configuration is included at the position where the contact region 24 is provided in planar view, illustration and description thereof may be omitted. The following description will be given by exemplifying the charge accumulation region FD out of the contact region 24 and the charge accumulation region FD. For the contact region 24, the charge accumulation region FD may be replaced with the contact region 24.

### First Semiconductor Region

As illustrated in FIGS. 4F and 4G, the first semiconductor region 20a1 is provided between the insulating region 26 and the first surface S1 in the thickness direction and has one surface that is in contact with the surface of the insulating region 26 near the first surface S1 and the other surface facing the first surface S1. More specifically, the first semiconductor region 20a1 is a part provided on the surface of the insulating region 26 near the first surface S1 in the cell region 20a and is a part overlapping the insulating region 26 in planar view.

FIG. 4D is a diagram illustrating the cell regions 20a in planar view of the first semiconductor layer 20 from the side of the first surface S1. As illustrated in

FIG. 4D, the first semiconductor region 20a1 is provided for each cell region 20a. More specifically, the first semiconductor region 20a1 is provided over the entire edge portion of the cell region 20a when the first semiconductor region 20a1 is observed from the side of the first surface S1 in planar view. The first semiconductor regions 20a1 of the adjacent cell regions 20a are provided to be spaced apart from each other and are not in contact with each other. Note that the portion of each cell region 20a located on the side further inward than the insulating region 26 in planar view will be referred to as a second semiconductor region 20a2, which is distinguished from the first semiconductor region 20a1.

As illustrated in FIG. 4D, the charge accumulation region FD is configured in a region of the cell region 20a including at least a part of the first semiconductor region 20a1. More specifically, the charge accumulation region FD is configured in a region of the cell region 20a including both the first semiconductor region 20a1 and the second semiconductor region 20a2.

### Electrode

As illustrated in FIG. 4A, the light detection device 1 includes electrodes 70.

Although the electrodes 70 include electrodes 70 that are electrically connected to the charge accumulation region FD and electrodes 70 that are electrically connected to the contact region 24, an electrode 70 that is electrically connected to the charge accumulation region FD will be described here as an example since configurations of the both are similar to each other.

The electrode 70 is an electrode that connects a wiring connected to the reading circuit 15 and the charge accumulation region FD of each pixel 3, and one electrode 70 is provided for a plurality of (four in the present embodiment) pixels 3 sharing one reading circuit 15. As illustrated in FIG. 4E, the electrode 70 includes a trunk portion 71 and a head portion 72 that has one surface connected to one end portion of the trunk portion 71. As illustrated in FIG. 4F, the other end portion of the trunk portion 71 is in contact with the surface of the insulating region 26 near the first surface S1 (that is, the surface on the side opposite to the side of the trench separation wall 25), and the electrode 70 is in contact with the charge accumulation region FD via a side surface of the trunk portion 71 and one surface (the surface on the side of the first semiconductor layer 20) of the head portion 72. More specifically, the side surface of the trunk portion 71 and the one surface of the head portion 72 of the electrode 70 are in contact with a part of the first semiconductor region 20a1 where the charge accumulation region FD is configured. Note that this does not exclude the side surface of the trunk portion 71 and the one surface of the head portion 72 of the electrode 70 being in contact with the second semiconductor region 20a2 where the charge accumulation region FD is configured. The side surface of the trunk portion 71 is a surface connecting the one end portion and the other end portion of the trunk portion 71. Also, the other surface of the head portion 72 faces the first wiring layer 30, and a wiring 32 is connected to the other surface of the head portion 72. As illustrated in FIGS. 4E and 4F, the head portion 72 extends in a plate shape in the horizontal direction, and the area of the one surface of the head portion 72 is larger than the area of one end portion of the trunk portion 71. Therefore, the head portion 72 can stick out from the trunk portion 71 in the horizontal direction in a longitudinal sectional view and can be in contact with the charge accumulation region FD as illustrated in FIG. 4F. As illustrated in FIG. 4D, the electrode 70 is provided at a position where the charge accumulation regions FD face each other in planar view. As illustrated in FIG. 4E, the trunk portion 71 separates (sections) the cell regions 20a, more specifically, the charge accumulation regions FD.

One electrode 70 is in contact with a plurality of charge accumulation regions FD sharing one reading circuit 15. More specifically, one electrode 70 is in contact with a plurality of (four in the present embodiment) charge accumulation regions FD provided in mutually different cell regions 20a. As illustrated in FIG. 4H, the trunk portion 71 includes a first extending part 71x extending in the row direction and the thickness direction and a second extending part 71y extending in the column direction and the thickness direction. The first extending part 71x and the second extending part 71y intersect each other at their centers, more specifically perpendicularly intersect each other in planar view. The part where they intersect each other will be referred to as an intersecting part 71c. The charge accumulation region FD is in contact with each of the four recessed corner portions of the trunk portion 71 configured by the first extending part 71x and the second extending part 71y.

FIG. 4F is a longitudinal sectional view illustrating a portion of a sectional configuration taken along the plane along the cut line A-A in FIG. 4D. In a case where the distance between two charge accumulation regions FD facing each other via the trunk portion 71 in the longitudinal sectional view in FIG. 4F is defined as b, and the dimension of the insulating region 26 in the horizontal direction is defined as a, the relationship that the distance b is smaller than the dimension a (b<a) is satisfied. Also, in a case where the dimension of the head portion 72 in the horizontal direction in the longitudinal sectional view is defined as c, the relationship that the dimension c is equal to or greater than b (b≤c) is satisfied. In a case where the dimension c and the distance b are equal to each other, this means that the head portion 72 is not provided with a part sticking out from the trunk portion 71.

The relationships among the distance b, the dimension a, and the dimension c are the same even in a case where the section of the intersecting part 71c is seen along a plane along a cut line that is different from the cut line A-A. Also, the relationships among the distance b, the dimension a, and the dimension c are the same even in a sectional configuration in a case where the light detection device 1 longitudinally taken along a plane along a cut line that does not cross the intersecting part 71c and crosses the first extending part 71x or the second extending part 71y in planar view is seen.

A material constituting the electrode 70 is a known conductive material. The material constituting the electrode 70 may be a known metal material such as aluminum (Al), copper (Cu), or tungsten (W). The present embodiment will be described on the assumption that the electrode 70 is configured of polysilicon (poly-Si).

Note that the electrode 70 that is electrically connected to the contact region 24 may be referred to as a contact electrode 70 to distinguish it from the electrode 70 that is electrically connected to the charge accumulation region FD. In that case, the trunk portion 71 and the head portion 72 of the contact electrode 70 will be referred to as a contact trunk portion 71 and a contact head portion 72.

### Transfer Transistor

As illustrated in FIGS. 4A and 4E, the transfer transistor T1 is provided for each cell region 20a. The transfer transistor T1 is a transistor capable of transferring a signal charge generated inside of the photoelectric conversion unit 22 to the charge accumulation region FD. For example, in a case where the transfer transistor T1 is turned on, conduction is established between the photoelectric conversion unit 22 and the charge accumulation region FD, and the signal charge is transferred to the charge accumulation region FD. Then, in a case where the transfer transistor T1 is turned off, the conduction between the photoelectric conversion unit 22 and the charge accumulation region FD is disconnected.

The transfer transistor T1 includes a gate electrode G1. As illustrated in FIG. 4A, the gate electrode G1 includes a columnar-shaped first part Gla buried in the cell region 20a and extending in the thickness direction and a second part G1b provided inside of the first wiring layer 30, is connected to an end portion of the first part Gla near the first surface S1, and extending in a plate shape in the horizontal direction. Note that in the drawings such as FIG. 4A, illustration of a gate insulating film that establishes insulation between the first part Gla and the cell region 20a is omitted.

### First Wiring Layer

As illustrated in FIG. 4A, the first wiring layer 30 is a multilayered wiring layer that has one surface in contact with the first semiconductor layer 20 and the other surface in contact with the second wiring layer 50. The first wiring layer 30 includes, for example, an insulating film 31 and a wiring 32 provided inside of the insulating film 31 although the first wiring layer 30 is not limited thereto.

The wiring 32 includes a longitudinal wiring extending mainly in the thickness direction and a horizontal wiring extending mainly in the horizontal direction.

The insulating film 31 has a configuration in which a plurality of known insulating films such as a silicon oxide (SiO₂) film, a silicon nitride (Si₃N₄) film, and a silicon oxynitride (SiON) film, for example, are stacked. The wiring 32 is a known conductive material such as a semiconductor material such as polysilicon or a metal material such as copper (Cu), tungsten (W), or aluminum (Al), for example.

### Second Semiconductor Layer

The second semiconductor layer 40 is configured of a semiconductor substrate. The second semiconductor layer 40 is configured of, for example, a single-crystal silicon substrate and has one surface in contact with the first wiring layer 30 and the other surface in contact with the second wiring layer 50 although the second semiconductor layer 40 is not limited thereto. The second semiconductor layer 40 is provided with a plurality of transistors T2. The transistors T2 include transistors configuring the reading circuit 15 illustrated in FIG. 3, for example.

### Second Wiring Layer

The second wiring layer 50 is a multilayered wiring layer that has one surface in contact with the second semiconductor layer 40 and the other surface in contact with a third semiconductor layer, illustration of which is omitted. The second wiring layer 50 includes, for example, a plurality of stacked insulating films 51 and wirings 52 provided inside of the insulating films 51 although the second wiring layer 50 is not limited thereto. The wirings 52 include longitudinal wiring extending mainly in the thickness direction and horizontal wirings extending mainly in the horizontal direction. The longitudinal wirings may include penetrating wirings that penetrate the second semiconductor layer as illustrated in FIG. 4A. The wiring 52 include longitudinal wiring extending mainly in the thickness direction and horizontal wiring extending mainly in the horizontal direction. The insulating films 51 have a configuration in which a plurality of known insulating films such as a silicon oxide (SiO₂) film, a silicon nitride (Si₃N₄) film, and a silicon oxynitride (SiON) film, for example, are stacked. The wiring 52 is a known conductive material such as a semiconductor material such a polysilicon or a metal material such as copper (Cu), tungsten (W), or aluminum (Al), for example.

The wirings 52 and the wiring 32 in the first wiring layer 30 configure electric pathways such as an electric pathway that establishes connection between the head portion 72 of the electrode 70 connected to the charge accumulation region FD and the amplification transistor AMP and an electric pathway that supplies a reference potential to the head portion 72 of the electrode 70 connected to the contact region 24, for example.

### Third Semiconductor Layer

The third semiconductor layer, illustration of which is omitted, is configured of a semiconductor substrate. The third semiconductor layer is configured of, for example, a single-crystal silicon substrate and has one surface in contact with the second wiring layer 50 although the third semiconductor layer is not limited thereto. The third semiconductor layer is provided with, for example, a transistor configuring the logic circuit 13 illustrated in FIG. 2.

### Light Incident Surface-Side Stacked Body

A light incident surface-side stacked body 60 has a stacked structure in which a flattened film 61, a color filter 62, a light shielding wall 63, and a micro-lens (on-chip lens) 64 are stacked in this order from the side of the second surface S2, for example, although the light incident surface-side stacked body 60 is not limited thereto. The flattened film 61 is configured of a known insulating material or a known resin material and may be configured of silicon oxide, for example, although the flattened film 61 is not limited thereto. The color filter 62 performs color-separation on light incident on each cell region 20a. The light shielding wall 63 the color filter 62 is configured of a resin material, for example. The light shielding wall 63 that shields stray light is provided between the color filters 62. The micro-lens 64 is configured of, for example, a resin material.

### Method for Manufacturing Light Detection Device

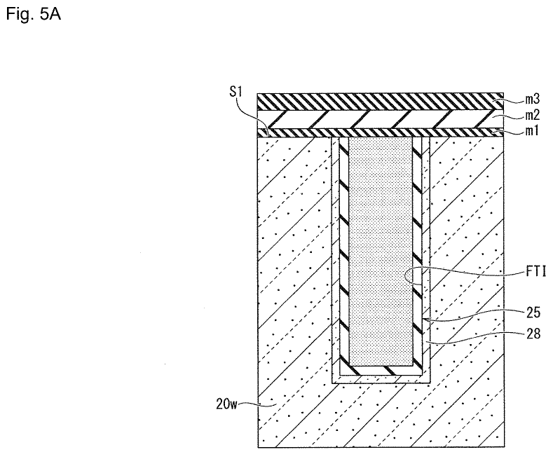

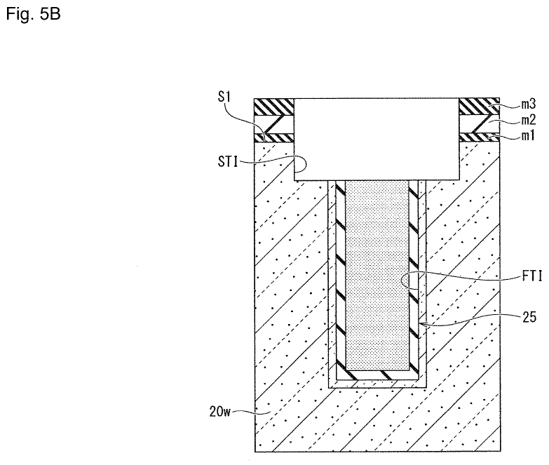

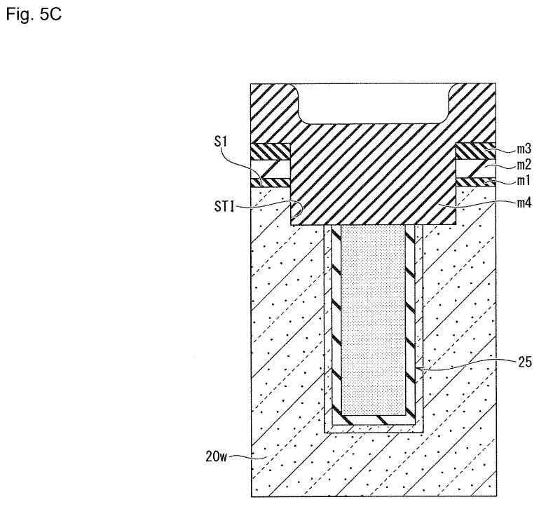

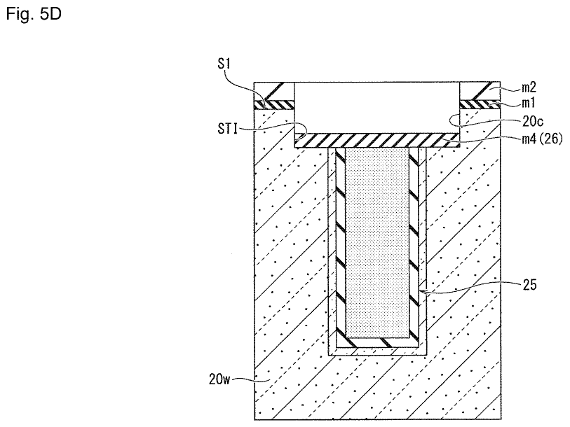

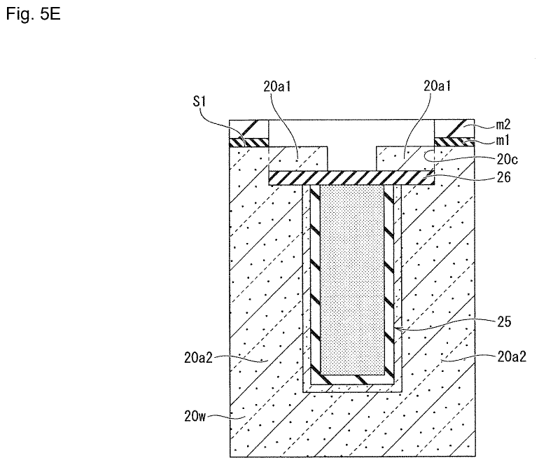

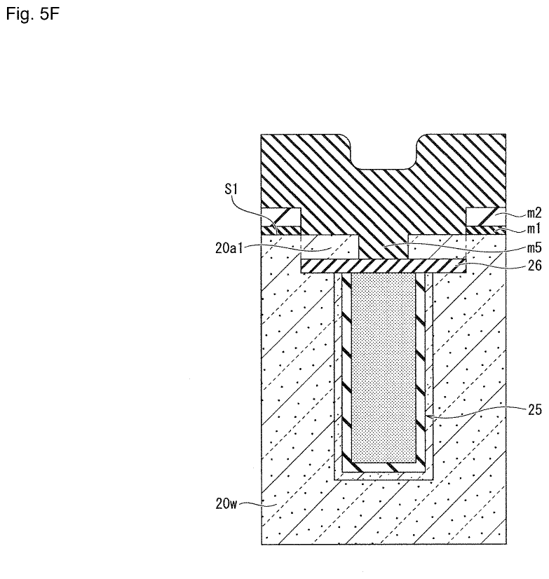

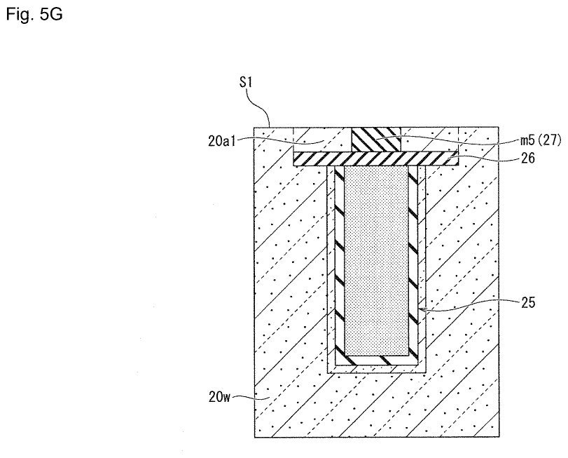

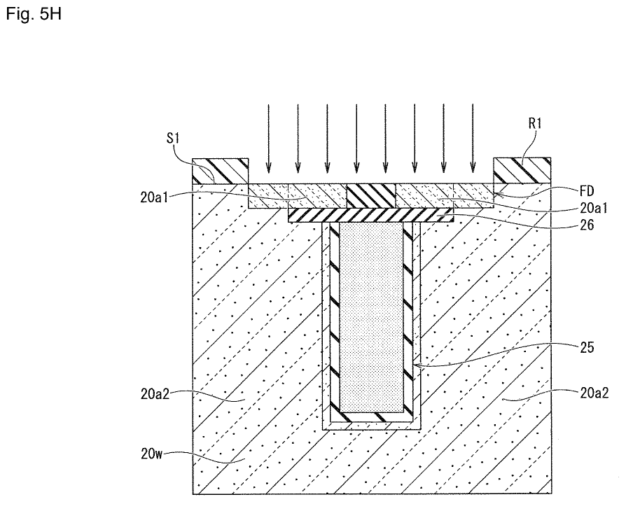

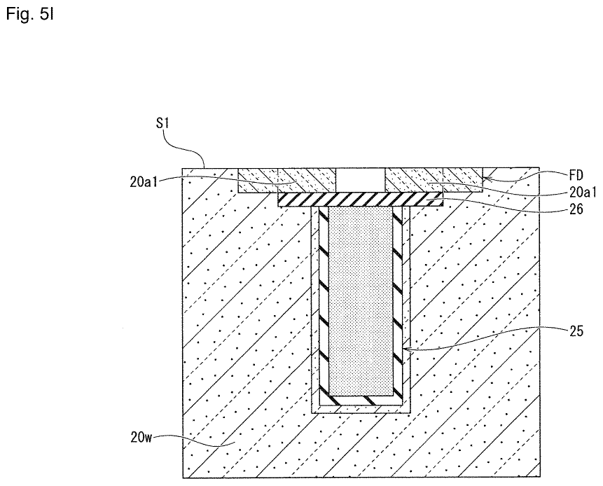

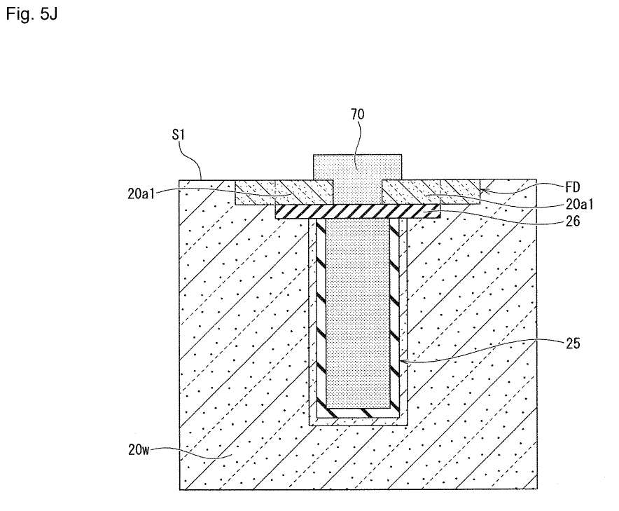

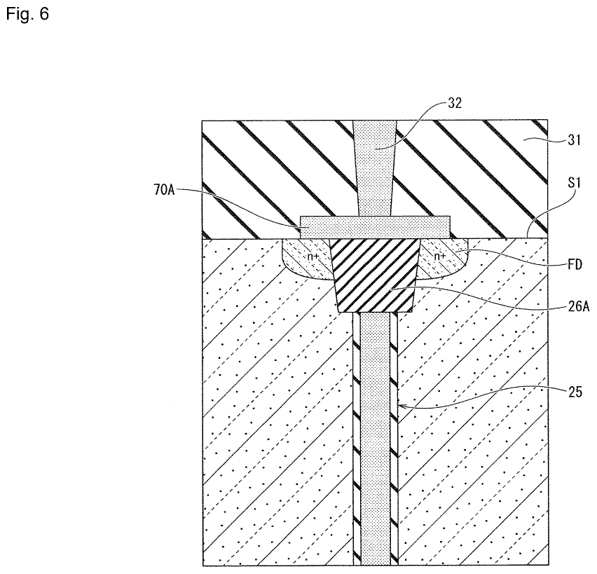

Hereinafter, a method of manufacturing the light detection device 1 will be described with reference to FIGS. 5A to 5J. Note that methods of forming the insulating region 26, the charge accumulation region FD, and the electrode 70 will be mainly described and description of the other parts will be omitted in the present embodiment.

First, the trench separation wall 25 buried in the groove FTI is formed from the side of the first surface S1 of the first semiconductor layer 20w by a known method as illustrated in FIG. 5A. An outer periphery of the trench separation wall 25 is provided with a first conductive (p-type, for example) pinning region 28. Thereafter, an insulating film m1, an insulating film m2, and an insulating film m3 are formed on the first surface S1 in this order. The insulating films m1 and m3 are, for example, silicon oxide films, and the insulating film m1 may be formed by thermal oxidation. The insulating film m2 is, for example, a silicon nitride film.

Next, the insulating region 26 is formed using the shallow trench isolation (STI) technology. Specifically, a groove STI is formed from the side of the first surface S1 first such that the groove STI overlaps the trench separation wall 25 in planar view, using a known lithograph technology and etching technology as illustrated in FIG. 5B. The groove STI is provided in a grid shape at a position where the groove STI overlaps the trench separation wall 25 in planar view. At that time, the insulating films m1, m2, and m3 are etched first using a resist pattern as a mask, and the groove STI is then formed using the insulating films as hard masks. The groove STI penetrates through the insulating films m1, m2, and m3 and reaches the inside of the first semiconductor layer 20w. Then, a part of the trench separation wall 25 near the first surface S1 is removed when the groove STI is formed. The dimension of the groove STI in the width direction is greater than the dimension of the groove FTI (the trench separation wall 25) in the width direction in planar view. The groove STI is provided over the entire location where the trench separation wall 25 is provided in planar view. In addition, the trench separation wall 25 is exposed from the bottom surface of the groove STI.

Thereafter, the insulating film m4 is formed to bury the inside of the groove STI as illustrated in FIG. 5C. The insulating film m4 is, for example, a silicon oxide film. Then, an unnecessary part of the insulating film m4 is removed by performing etch back on the entire surface as illustrated in FIG. 5D. The insulating film m4 remaining on the bottom portion of the groove STI configures the insulating region 26. Note that the insulating film m3 is removed at the time of the etch back on the entire surface. The etching rate of the insulating film m2 is lower than etching rates of the insulating film m4 and the insulating film m3, and the insulating film m2 is slightly etched if it is etched.

Furthermore, a semiconductor configuring the first semiconductor layer 20w is exposed from the side wall of the groove STI through the etch back. The semiconductor surface exposed from the side wall of the groove STI will be referred to as a surface 20c.

Next, the first semiconductor region 20a1 is obtained by causing silicon to epitaxially grow on the surface 20c as illustrated in FIG. 5E. The first semiconductor region 20a1 obtained through the epitaxial growth is, for example, an intrinsic semiconductor (i-type) although the first semiconductor region 20a1 is not limited thereto, and the first semiconductor region 20a1 may be a p-type or n-type semiconductor in accordance with design. Furthermore, the first semiconductor region 20a1 may be formed to have the same conductivity type as the conductivity type of the second semiconductor region 20a2 or the semiconductor region 21 in accordance with design or may be formed to have a different conductivity type. Silicon is selectively caused to epitaxially grow on the surface 20c made of a semiconductor and does not grow on a surface made of a material other than the semiconductor, such as an insulating film, for example. Further, the epitaxial growth is caused with a growth time controlled to prevent the first semiconductor regions 20a1 growing on the facing surfaces 20c from being connected to each other.

Thereafter, an insulating film m5 is formed to cover the first semiconductor regions 20a1 and bury the clearance between the first semiconductor regions 20a1 as illustrated in FIG. 5F. Then, an extra part of the insulating film m5 and the insulating films m1 and m2 are removed by a known method such as a known chemical-mechanical polishing (CMP) method or etch back. In this manner, the insulating film m5 remaining between the first semiconductor regions 20a1 configures the narrow width insulating region 27, and the first semiconductor region 20a1 and the first surface S1 are exposed as illustrated in FIG. 5G.

Next, a resist pattern R1 is formed in the exposed surface as illustrated in FIG. 5H. The resist pattern R1 has an opening at a position where the charge accumulation region FD is formed. Both the first semiconductor region 20a1 and the second semiconductor region 20a2 are exposed from the opening. Then, the charge accumulation region FD is formed by selectively ion injecting known impurities to obtain an n-type semiconductor using the resist pattern R1 as an ion injection mask. Thereafter, the resist pattern R1 is removed. Although not illustrated, the contact region 24 is also similarly formed. However, impurities to be injected are known impurities to obtain a p-type semiconductor.

Then, the narrow width insulating region 27 at the position where the electrode 70 is provided in planar view is removed using a known lithography technology and etching technology as illustrated in FIG. 5I. Thereafter, a polysilicon film is formed by a known film formation technology to cover the first surface S1 and bury the clearance between the first semiconductor regions 20a1 as illustrated in FIG. 5J. Then, an extra part of the polysilicon film is etched using a known lithography technology and etching technology, thereby obtaining the electrode 70. Thereafter, the processing is continued using a known manufacturing method, thereby substantially completing the light detection device 1. Then, the light detection device 1 is obtained as each piece, thereby obtaining the semiconductor chip 2.

### Main Effects of First Embodiment

Although main effects of the first embodiment will be described below, a light detection device according to a comparative example illustrated in FIG. 6 will be described first. In the comparative example, an end portion of a trench separation wall 25 near a first surface S1 is provided with a shallow trench 26A with an insulating film buried therein. Also, four charge accumulation regions FD are sectioned by the shallow trench 26A. An electrode 70A is made only of a plate-shaped member extending in the horizontal direction and is in contact with the four charge accumulation regions FD via a surface on the side of a first semiconductor layer 20.

With refinement of pixels 3, a decrease in dimensions of the charge accumulation regions FD and the electrode 70A is also required. However, the decrease in dimensions of the charge accumulation regions FD and the electrode 70A may lead to a decrease in contact area between the charge accumulation regions FD and the electrode 70A and thus an increase in contact resistance. This may lead to degradation of electrical connection between the charge accumulation regions FD and the electrode 70A.

On the other hand, the light detection device 1 according to the first embodiment of the present technology includes the electrode 70 that includes the trunk portion 71 and the head portion 72 having one surface connected to one end portion of the trunk portion 71, the charge accumulation region FD is configured in the region of each cell region 20a including a part of the first semiconductor region 20a1, the other end of the trunk portion 71 is in contact with the one surface of the insulating region 26 (the surface near the first surface S1), and the electrode 70 is in contact with the charge accumulation region FD via the side surface of the trunk portion 71 and the one surface of the head portion 72. Since contact with the charge accumulation region FD is established at the side surface of the trunk portion 71 in addition to the one surface of the head portion 72 in the light detection device 1 according to the first embodiment of the present technology in this manner, it is possible to curb a decrease in contact area between the charge accumulation region FD and the electrode 70 and to curb degradation of electrical connection between the charge accumulation region FD and the electrode 70. It is thus possible to curb degradation of the electrical connection between the charge accumulation region FD and the electrode 70 even in a case where refinement of the pixels 3 is achieved.

Also, in the light detection device 1 according to the first embodiment of the present technology, each cell region 20a includes the first semiconductor region 20a1 provided on the surface of the insulating region 26 on the side opposite to the surface on the side of the trench separation wall 25. In this manner, it is possible to increase the region occupied by the cell region 20a on the side of the first surface S1 up to the portion above the insulating region 26, to configure the charge accumulation region FD over the entire increased region, and to thereby curb a decrease in dimension of the charge accumulation region FD. Therefore, it is possible to curb a decrease in contact area between the charge accumulation region FD and the electrode 70 and to curb degradation of electrical connection between the charge accumulation region FD and the electrode 70. It is thus possible to curb degradation of the electrical connection between the charge accumulation region FD and the electrode 70 even in a case where refinement of the pixels 3 is achieved.

Furthermore, it is possible to increase the region occupied by the cell region 20a on the side of the first surface S1 up to the portion above the insulating region 26 and to thereby curb a decrease in overlapping margin between the electrode 70 and the charge accumulation region FD. Moreover, it is possible to increase the region occupied by the cell region 20a on the side of the first surface S1 up to the portion above the insulating region 26, and this leads to an increase in degree of freedom in arrangement of the gate electrode G1.

Also, in the light detection device 1 according to the first embodiment of the present technology, the side surface of the trunk portion 71 and the one surface of the head portion 72 are in contact with the part of the first semiconductor region 20a1 where the charge accumulation region FD is configured. Since the electrode 70 is in contact with the charge accumulation region FD configured in the first semiconductor region 20a1, it is possible to curb a decrease in contact area between the charge accumulation region FD and the electrode 70 while curbing a decrease in dimension of the electrode 70, more specifically, the dimension of the head portion 72 in planar view. In other words, it is possible to increase the contact area between the charge accumulation region FD and the electrode 70 when the dimension of the head portion 72 in planar view is the same.

Furthermore, the contact region 24 also has the same effects as those of the aforementioned charge accumulation region FD in the light detection device 1 according to the first embodiment of the present technology.

Note that although the head portion 72 is in contact with the charge accumulation region FD only in the first semiconductor region 20a1 out of the first semiconductor region 20a1 and the second semiconductor region 20a2 as illustrated in FIG. 4E in the present embodiment, the head portion 72 may be in contact with the charge accumulation region FD both in the first semiconductor region 20a1 and the second semiconductor region 20a2.

### MODIFICATION EXAMPLES OF FIRST EMBODIMENT

A modification example of the first embodiment will be described below.

### First Modification Example

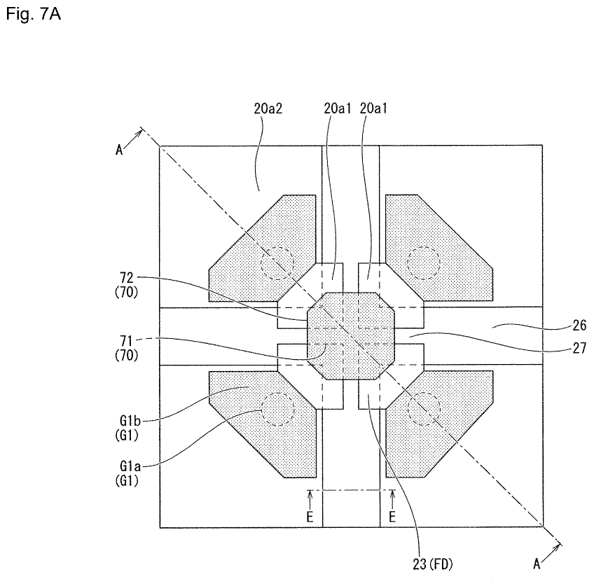

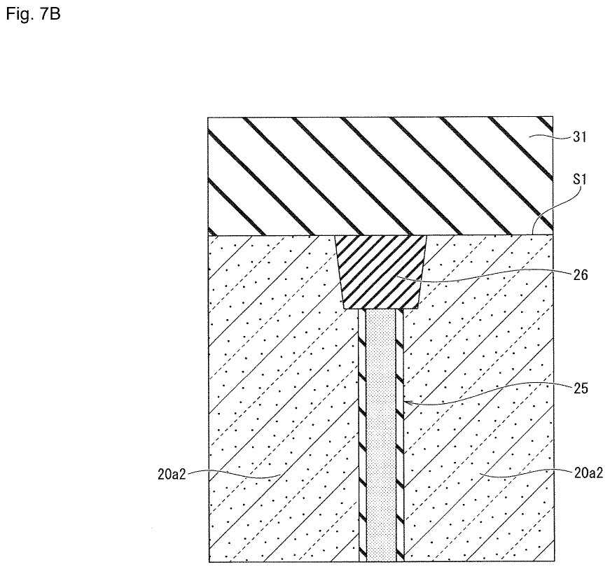

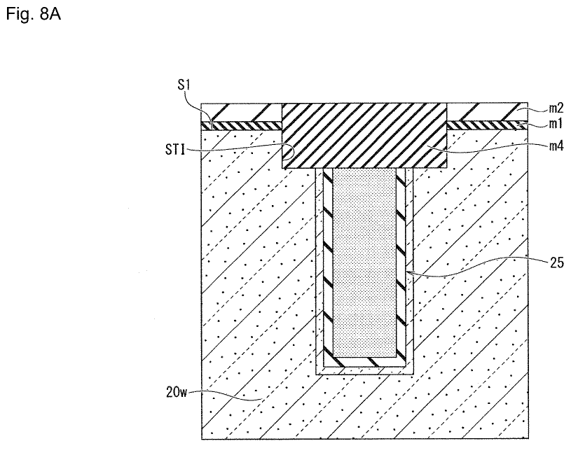

Although the first semiconductor region 20a1 is provided over the entire edge portion of the cell region 20a on the first surface S1 as illustrated in FIG. 4D in the light detection device 1 according to the first embodiment, the present technology is not limited thereto. In a light detection device 1 according to a first modification example of the first embodiment illustrated in FIG. 7A, the first semiconductor region 20a1 is provided only at corner portions of each cell region 20a on the first surface S1. The first semiconductor region 20a1 is not provided at a portion other than the corner portion as illustrated in FIG. 7B. The sectional configuration of the light detection device 1 longitudinally taken along the plane along the cut line A-A in FIG. 7A is the same as that in FIG. 4F. FIG. 7B illustrates a sectional configuration of the light detection device 1 longitudinally taken along the plane along the cut line E-E in FIG. 7A. As illustrated in FIG. 7B, the first semiconductor region 20a1 is not provided in a region other than the corner portion of each cell region 20a. As illustrated in FIG. 7A, the charge accumulation region FD is configured in a semiconductor region including the entire region of the first semiconductor region 20a1 provided at one corner portion of each cell region 20a.

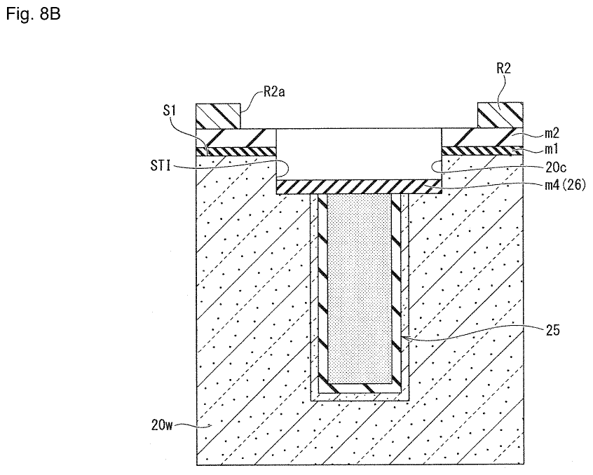

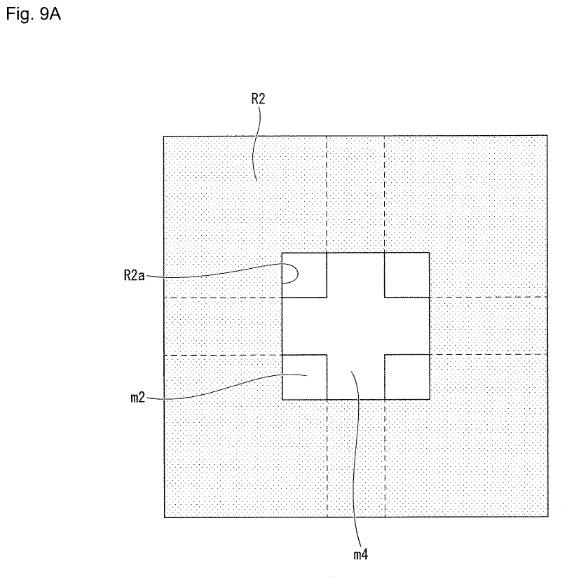

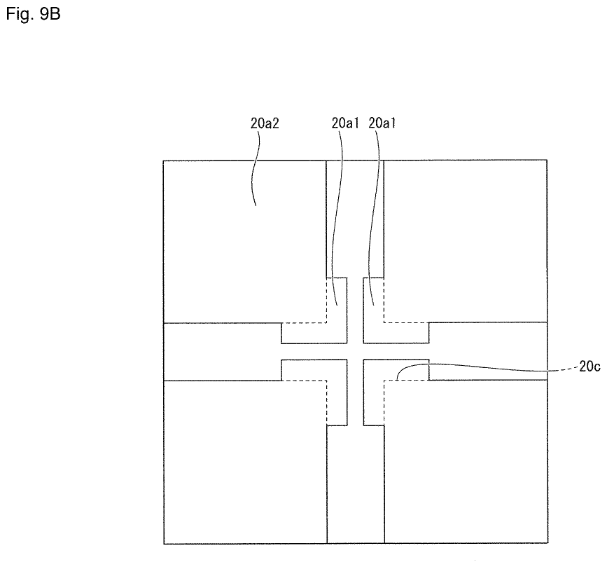

Hereinafter, a method of manufacturing the light detection device 1 will be described with reference to FIGS. 8A, 8B, 9A, and 9B. Note that only parts different from those in the aforementioned manufacturing method according to the first embodiment will be described in this modification example. The processes up to the one illustrated in FIG. 5C are performed in the same manner as in the aforementioned manufacturing method according to the first embodiment. Thereafter, an unnecessary part of the insulating film m4 and the insulating film m3 are removed by the CMP method as illustrated in FIG. 8A.

Then, a resist pattern R2 is formed on the exposed surface of the insulating film m2 as illustrated in FIG. 8B. The resist pattern R2 includes an opening R2a at a position where the charge accumulation region FD or the contact region 24 is provided as illustrated in FIGS. 8B and 9A. Also, etch back is performed on the insulating film m4 exposed from the opening R2a, and etch back is not performed on the part of the insulating film m4 covered with the resist. Note that the etching rate of the insulating film m2 is lower than the etching rates of the insulating film m4 and the insulating film m3, and the insulating film m2 is slightly etched if it is etched. Then, the insulating film m4 remaining on the bottom portion of the groove STI configures the insulating region 26 as illustrated in FIG. 8B. Thereafter, the resist pattern R2 is removed.

Next, silicon is caused to epitaxially grow on the surface 20c illustrated in FIG. 8B, thereby obtaining the first semiconductor region 20a1. Note that the part of the insulating film m4 that is protected by the resist pattern R2 and has not been etched back covers the side surface of the cell region 20a as illustrated in FIG. 7B. Therefore, silicon is caused to epitaxially grow only at the corner portion while silicon is not caused to epitaxially grow at a portion other than the corner portion as illustrated in FIG. 9B.

Effects similar to those of the aforementioned light detection device 1 according to the first embodiment are obtained even by the light detection device 1 according to the first modification example of the first embodiment.

In the light detection device 1 according to the first modification example of the first embodiment, it is possible to increase the region occupied by the cell region 20a on the side of the first surface S1 up to the portion above the insulating region 26 at the corner portion of the cell region 20a where the charge accumulation region FD or the contact region 24 is provided, to configure the charge accumulation region FD over the increased region, and to thereby curb a decrease in dimension of the charge accumulation region FD. Therefore, it is possible to curb a decrease in contact area between the charge accumulation region FD and the electrode 70 and to curb degradation of electrical connection between the charge accumulation region FD and the electrode 70. It is thus possible to curb degradation of the electrical connection between the charge accumulation region FD and the electrode 70 even in a case where refinement of the pixels 3 is achieved.

### Second Modification Example

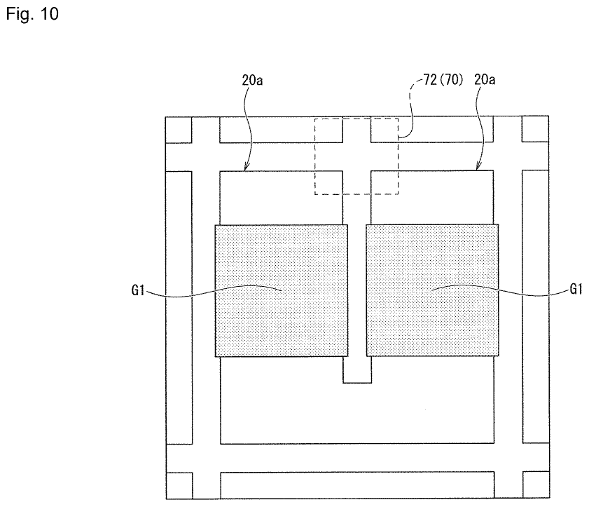

In a light detection device 1 according to a second modification example of the first embodiment illustrated in FIG. 10, a gate electrode G1 may have a rectangular shape and may have a larger area in planar view than that in the case of the first embodiment. Also, a head portion 72 of an electrode 70 may have a rectangular shape instead of an octagonal shape in planar view.

Furthermore, a pixel illustrated in FIG. 10 may be a phase difference detection unit that detects a phase difference. Note that illustration of a charge accumulation region FD is omitted in FIG. 10. Effects similar to those of the aforementioned light detection device 1 according to the first embodiment are obtained even by the light detection device 1 according to the second modification example of the first embodiment.

### Third Modification Example

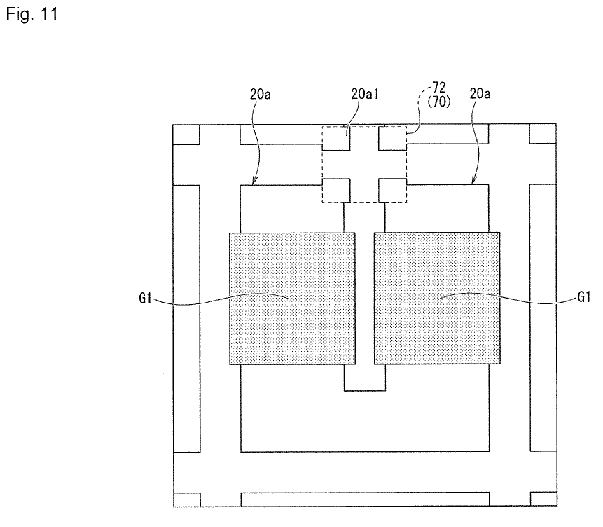

A light detection device 1 according to a third modification example of the first embodiment illustrated in FIG. 11 is a combination of the first modification example and the second modification example described above. More specifically, a first semiconductor region 20a1 is provided only at a corner portion of each cell region 20a, and a gate electrode G1 and a head portion 72 are the same as those in the aforementioned second modification example as illustrated in FIG. 11. Note that illustration of a charge accumulation region FD is omitted in FIG. 11. Effects similar to those of the aforementioned light detection device 1 according to the first embodiment are obtained even by the light detection device 1 according to the third modification example of the first embodiment.

### Fourth Modification Example

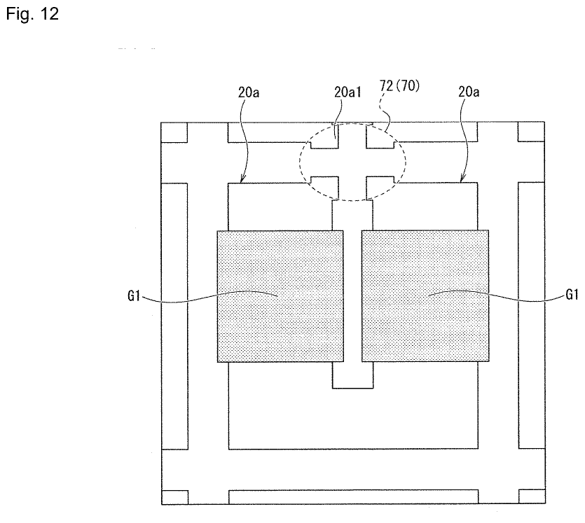

In a light detection device 1 according to a fourth modification example of the first embodiment illustrated in FIG. 12, a head portion 72 of an electrode 70 has an oval shape in planar view, and a first semiconductor region 20a1 is provided only at a corner portion of each cell region 20a. Note that illustration of a charge accumulation region FD is omitted in FIG. 12. Effects similar to those of the aforementioned light detection device 1 according to the first embodiment are obtained even by the light detection device 1 according to the fourth modification example of the first embodiment.

### Fifth Modification Example

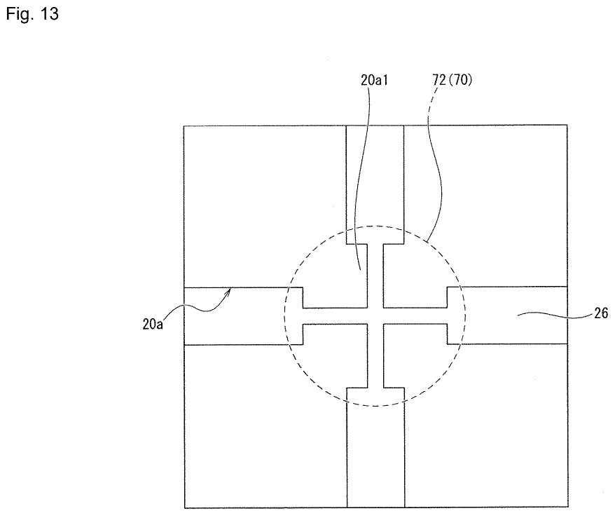

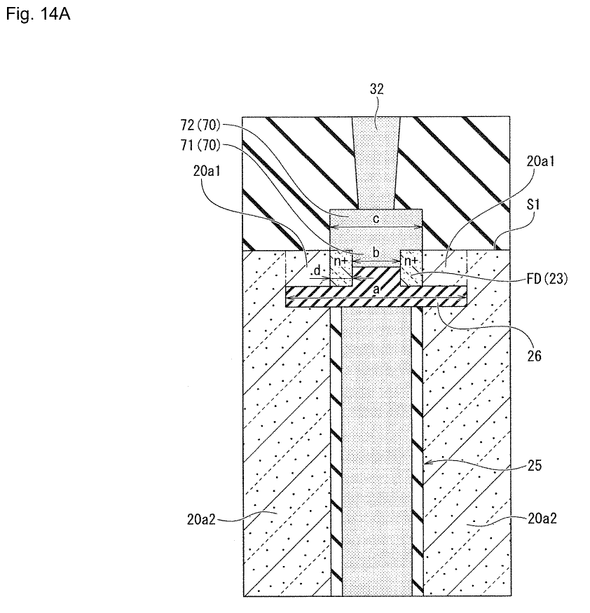

In a light detection device 1 according to a fifth modification example of the first embodiment illustrated in FIG. 13, a head portion 72 of an electrode 70 has a circular shape in planar view, and a first semiconductor region 20a1 is provided only at a corner portion of each cell region 20a. Note that illustration of a charge accumulation region FD is omitted in FIG. 13. Effects similar to those of the aforementioned light detection device 1 according to the first embodiment are obtained even by the light detection device 1 according to the fifth modification example of the first embodiment.

### Sixth Modification Example

Although the light detection device 1 (semiconductor chip 2) has three semiconductor layers, for example, the first semiconductor layer 20, the second semiconductor layer 40, and the third semiconductor layer, illustration of which is omitted, in the first embodiment and the modification examples thereof, the present technology is not limited thereto. A light detection device 1 according to a sixth modification example of the first embodiment may include only two layers, namely a first semiconductor layer 20 and a third semiconductor layer out of the three semiconductor layers. In that case, elements configured in the second semiconductor layer 40 may be configured in the first semiconductor layer 20 or the like. Effects similar to those of the aforementioned light detection device 1 according to the first embodiment are obtained even by the light detection device 1 according to the sixth modification example of the first embodiment.

### Second Embodiment

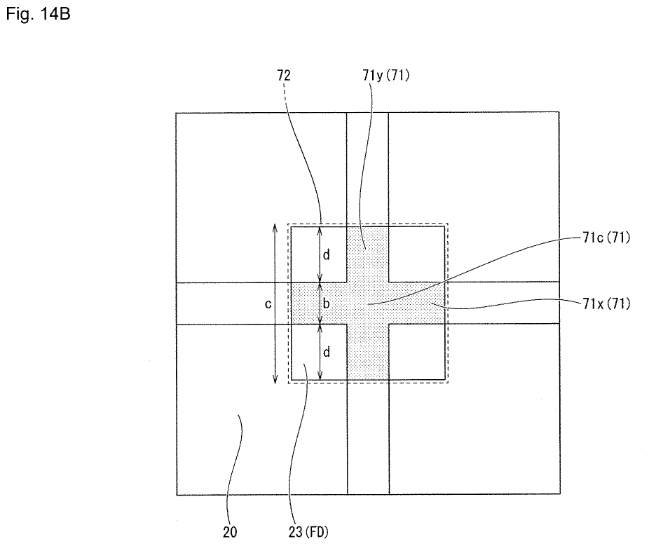

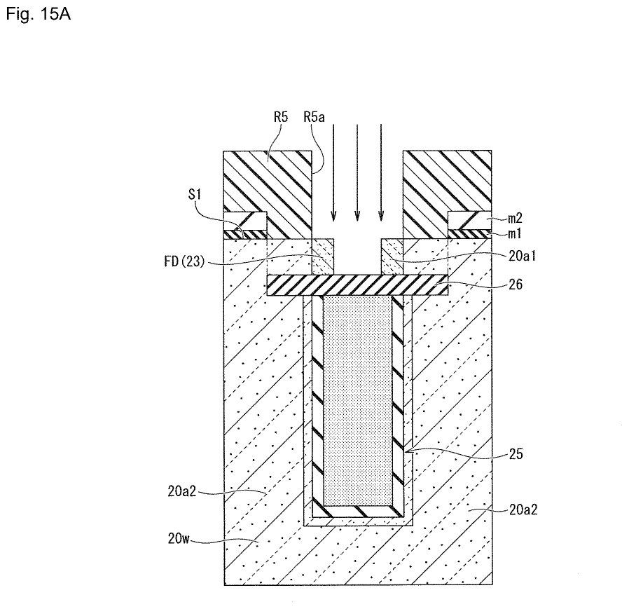

A second embodiment of the present technology illustrated in FIGS. 14A and 14B will be described below. In a light detection device 1 according to the second embodiment, the size of a region occupied by a charge accumulation region FD is different. The other configurations of the light detection device 1 are basically similar to the configurations of the aforementioned light detection device 1 according to the first embodiment. Note that the constituent elements that have already been described will be denoted by the same reference signs and description thereof will be omitted. Note that FIG. 14A is a longitudinal sectional view illustrating a sectional configuration of an electrode 70, a charge accumulation region FD, and an insulating region 26 taken along the plane along the cut line crossing a trunk portion 71. In the present embodiment, FIG. 14A is a longitudinal sectional view illustrating a sectional configuration of the electrode 70 taken along the plane along the cut line crossing a first extending part 71x of the trunk portion 71 illustrated in FIG. 14B as an example.

The charge accumulation region FD is configured in a region of each cell region 20a made only of the first semiconductor region 20a1. More specifically, the charge accumulation region FD is configured in a region made only of the first semiconductor region 20a1 out of the first semiconductor region 20a1 and a second semiconductor region 20a2 and is not configured in the second semiconductor region 20a2. Also, the entire charge accumulation region FD overlaps the insulating region 26 in planar view, and a surface of the charge accumulation region FD on the side of a second surface S2 is in contact with the insulating region 26. In other words, the region occupied by the charge accumulation region FD in the present embodiment is smaller than the region occupied by the charge accumulation region FD in the first embodiment.

Therefore, the impurity concentration in the charge accumulation region FD according to the present embodiment is set to be higher than the impurity concentration in the charge accumulation region FD according to the first embodiment. It is possible to curb degradation of performance to accumulate a charge by setting a high impurity concentration even if the region occupied by the charge accumulation region FD is reduced in size. Also, it is possible to curb an increase in contact resistance by setting a high impurity concentration even if the contact area between the charge accumulation region FD and the electrode 70 is reduced by the region occupied by the charge accumulation region FD being reduced in size.

The charge accumulation region FD is configured in a region made only of the first semiconductor region 20a1. Therefore, the relationship among a dimension a, which is the dimension of the insulating region 26 in the horizontal direction, a distance b, which is the distance between two charge accumulation regions FD facing each other via the trunk portion 71, and a dimension d, which is the dimension of the charge accumulation region FD in the horizontal direction in the longitudinal sectional view in FIG. 14A can be represented as a >2d+b. In other words, a value obtained by adding the value of the distance b to a value that is double the dimension d is equal to or less than the dimension a. In other words, 2d+b is the width occupied by the two charge accumulation regions FD facing each other via the trunk portion 71 in the horizontal direction.

Also, the head portion 72 overlaps the entire charge accumulation region FD in planar view as illustrated in FIGS. 14A and 14B. In other words, the relationship among the distance b and the dimension d described above and a dimension c of the head portion 72 in the horizontal direction can be represented as c≥2d+b. In other words, the dimension c is equal to or greater than a value obtained by adding the value of the distance b to the value of double the dimension d. In a case where the value of the dimension c is defined, it is only necessary to determine the distance b and the dimension d to satisfy the above expression.

A lower limit value of the dimension c may be the same width as the width of the trench separation wall 25, for example, although the lower limit value is not limited thereto. Also, a lower limit value of the dimension d may fall within a range of ¼ to ⅕ the dimension c, for example, although the lower limit value is not limited thereto.

Note that the relationship among the dimension a, the distance b, the dimension c, and the dimension d is the same in a sectional configuration different from that in FIG. 14A in a longitudinal sectional view along a plane.

### Method for Manufacturing Light Detection Device

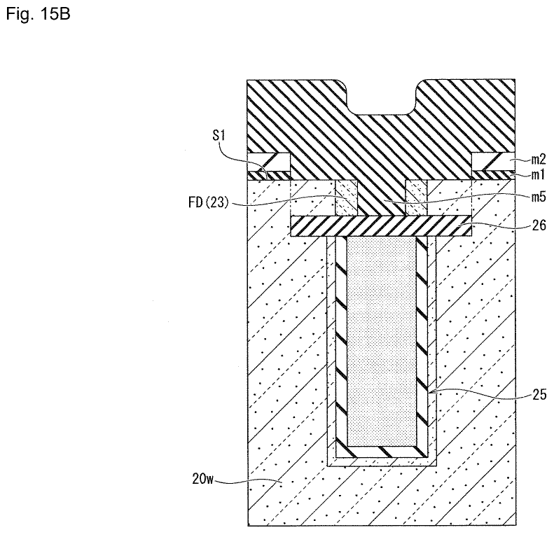

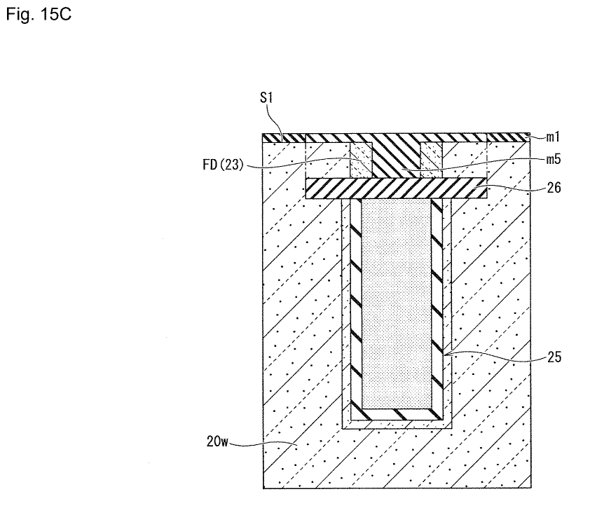

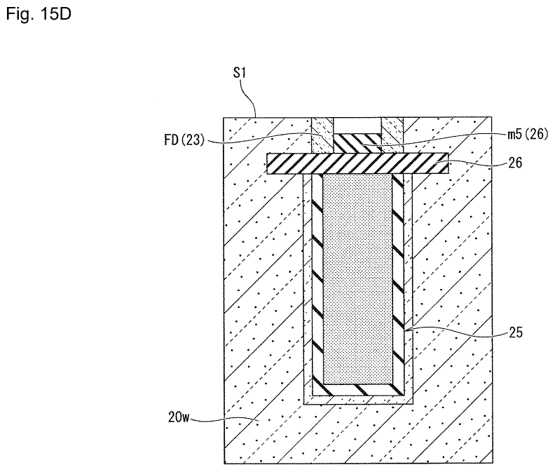

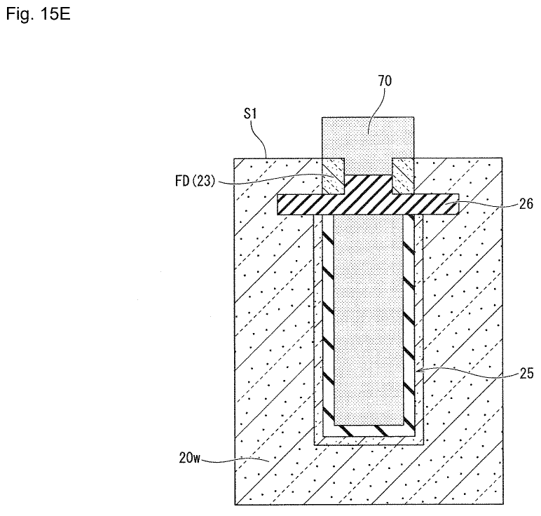

Hereinafter, a method of manufacturing the light detection device 1 will be described with reference to FIGS. 15A to 15E. Note that only parts different from those in the aforementioned manufacturing method according to the first embodiment will be described in this modification example. Also, the drawings used to describe the manufacturing method according to the first embodiment will also be referred to in the following description as needed.

The same processes as those up to FIG. 5E in the aforementioned manufacturing method according to the first embodiment are performed. Thereafter, a resist pattern R5 having an opening R5a is formed in the exposed surface as illustrated in FIG. 15A. Then, known impurities to obtain an n-type semiconductor is injected from the side of the first surface S1 using the resist pattern R5 as a mask for the ion injection. A resist configuring the resist pattern R5 covers a part of the first semiconductor region 20a1 obtained through epitaxial growth.

Also, another part of the first semiconductor region 20a1 is exposed from the opening R5a. It is possible to provide the charge accumulation region FD in a narrower region as compared with the case of the first embodiment by ion-injecting the impurities via such an opening R5a. Also, it is necessary to perform the ion injection with an increased dose in order to form the charge accumulation region FD in the narrow region. In the present embodiment, the entire opening R5a overlaps the insulating region 26 in planar view. In other words, the impurities are injected to the semiconductor region overlapping the surface of the insulating region 26 on the side of the first surface S1 in planar view. Therefore, even in a case where the dose of impurities is increased to raise the impurity concentration in the charge accumulation region FD, advancement of the impurities is blocked by the insulating region 26, and it is difficult for the impurities to reach a deeper position. It is thus possible to cause the impurities to remain at a high concentration in a region where it is desired to form the charge accumulation region FD and to form a fine charge accumulation region FD with a high impurity concentration.

Next, the insulating film m5 is formed on the exposed surface to bury the charge accumulation regions FD as illustrated in FIG. 15B. Then, an extra part of the insulating film m5 is removed by the CMP method, and the insulating film m2 is then removed, thereby obtaining the state illustrated in FIG. 15C. Then, the insulating film m1 and an extra part of the insulating film m5 are removed by etch back as illustrated in FIG. 15D. A portion of the insulating film m5 is caused to remain between the charge accumulation regions FD, and the remaining insulating film m5 and the insulating region 26 will be collectively referred to as an insulating region 26 below. Next, the electrode 70 is formed such that the electrode 70 is in contact with each charge accumulation region FD as illustrated in FIG. 15E. The following processing is the same as the processing described in the first embodiment, and description will be omitted.

### Main Effects of Second Embodiment

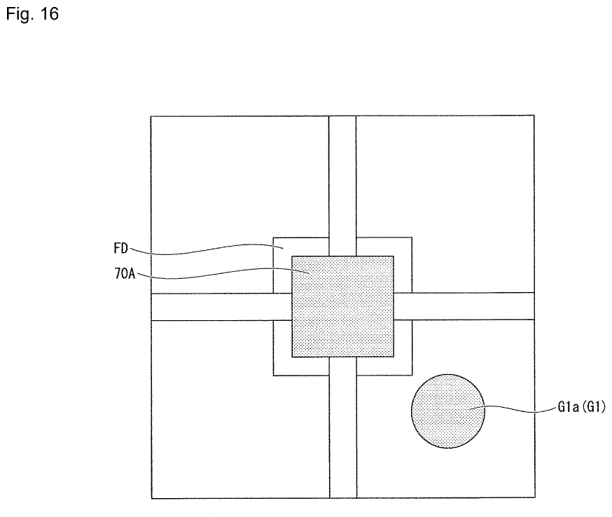

Although main effects of the second embodiment will be described below, a light detection device according to a comparative example illustrated in FIG. 16 will be described first. As illustrated in FIG. 16, if the distance between the charge accumulation region FD and a first part Gla with a columnar shape included in the gate electrode G1 is excessively short in planar view, then a field intensity between the charge accumulation region FD and the first part Gla may become large, and an FD white spot may deteriorate. However, if refinement of the charge accumulation region FD and the electrode 70A is achieved to widen the distance between the charge accumulation region FD and the first part Gla, then the contact area between the charge accumulation region FD and the electrode 70A may decrease, and this may lead to an increase in contact resistance. This may lead to degradation of electrical connection between the charge accumulation regions FD and the electrode 70A.

On the other hand, the light detection device 1 according to the second embodiment of the present technology can obtain effects similar to those of the aforementioned light detection device 1 according to the first embodiment.

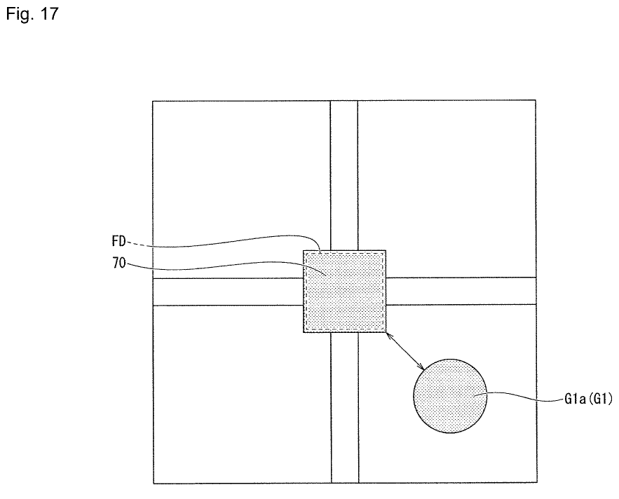

Furthermore, in the light detection device 1 according to the second embodiment of the present technology, the charge accumulation region FD is configured in a region made only of the first semiconductor region 20a1 in the cell region 20a, and the entire charge accumulation region FD overlaps the insulating region 26 in planar view. In this manner, it is possible to form the fine charge accumulation region FD with a high impurity concentration. Therefore, it is possible to widen the distance between the charge accumulation region FD and the first part Gla as compared with the comparative example as illustrated in FIG. 17 in the light detection device 1 according to the second embodiment of the present technology. It is thus possible to curb an increase in field intensity between the charge accumulation region FD and the first part Gla and to curb degradation of the FD white spot. Furthermore, it is possible to form the charge accumulation region FD with a high impurity concentration, to thereby curb degradation of performance of accumulating a charge even if the region occupied by the charge accumulation region FD decreases in size, and to curb an increase in contact resistance between the charge accumulation region FD and the electrode 70 even if the contact area therebetween decreases.

In the light detection device 1 according to the second embodiment of the present technology, the relationship of c≥2d+b is satisfied in the case where the distance between the two charge accumulation regions FD facing each other via the trunk portion 71 is defined as b, the dimension of the head portion 72 in the horizontal direction is defined as c, and the dimension of each charge accumulation region FD in the horizontal direction is defined as d in longitudinal sectional view. In other words, since the head portion 72 overlaps each entire charge accumulation region FD in planar view, it is possible to effectively bring the head portion 72 of the electrode 70 into contact with the charge accumulation region FD even if the region occupied by the charge accumulation region FD decreases in size. Note that if the contact area between the charge accumulation region FD and the electrode 70 is the same as that in the case of the first embodiment, it is possible to reduce the contact resistance as compared with that in the case of the first embodiment since the impurity concentration in the charge accumulation region FD is higher in the present embodiment. Also, even if the contact area between the charge accumulation region FD and the electrode 70 is smaller than that in the case of the first embodiment, it is possible to curb an increase in contact resistance since the impurity concentration in the charge accumulation region FD is higher in the present embodiment.

Furthermore, the width occupied by the two charge accumulation regions FD facing each other via the trunk portion 71 in the horizontal direction in longitudinal sectional view is equal to or less than the dimension of the insulating region 26 in the horizontal direction in the sectional view in the light detection device 1 according to the second embodiment of the present technology. In this manner, it is possible to form the fine charge accumulation region FD with a high impurity concentration even in a case where one electrode 70 is provided with respect to the plurality of charge accumulation regions FD.

### MODIFICATION EXAMPLES OF SECOND EMBODIMENT

Hereinafter, modification examples of the second embodiment will be described.

### First Modification Example

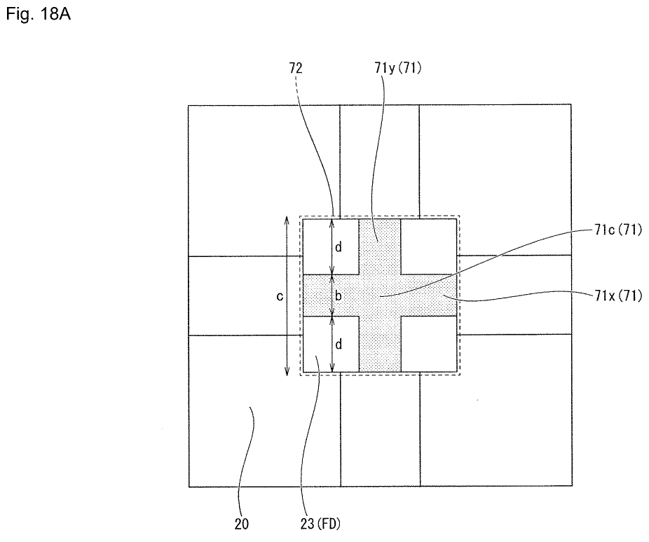

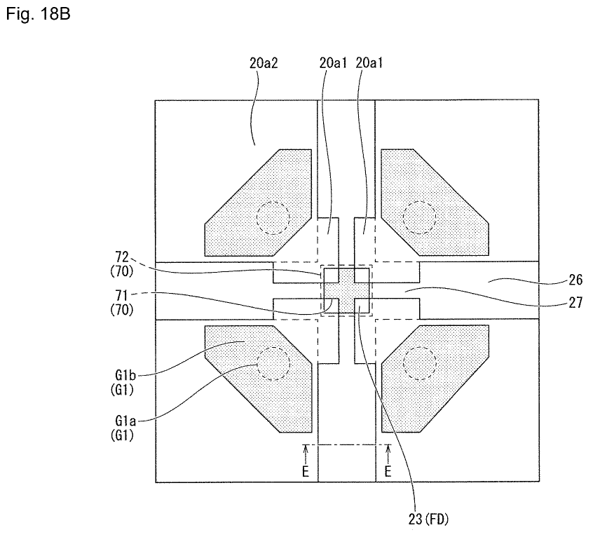

A light detection device 1 according to a first modification example of the second embodiment illustrated in FIG. 18A is a combination of the first modification example of the first embodiment and the second embodiment. More specifically, a first semiconductor region 20a1 is provided only at a corner portion of each cell region 20a, and the charge accumulation region FD in the second embodiment is provided in such a first semiconductor region 20a1 as illustrated in FIG. 18A.

The relationship of a dimension a, a distance b, a dimension c, and a dimension d is the same in this modification example as well. Also, the positional relationship and the size relationship among an electrode 70, the charge accumulation region FD, and the first semiconductor region 20a1 may be the relationships illustrated in FIG. 18B. Effects similar to those of the aforementioned light detection device 1 according to the second embodiment are obtained even by the light detection device 1 according to the first modification example of the second embodiment.

### Second Modification Example

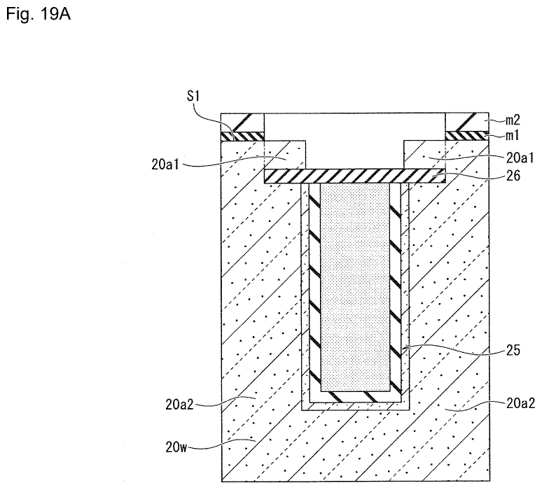

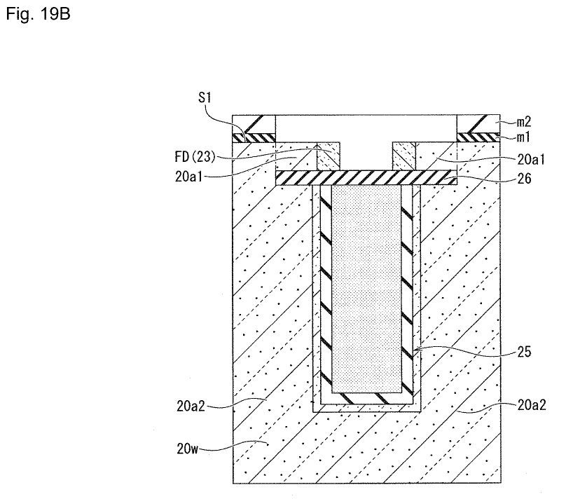

A light detection device 1 according to a second modification example of the second embodiment is different from that in the second embodiment in its manufacturing method. Hereinafter, the method of manufacturing the light detection device 1 according to this modification example will be described with reference to FIGS. 19A and 19B. Note that only parts different from those in the aforementioned manufacturing methods according to the first embodiment and the second embodiment will be described in this modification example. Also, the drawings used to describe the manufacturing method according to the first embodiment will also be referred to in the following description as needed.

The processes up to those in FIG. 5D are the same as those in the aforementioned manufacturing method according to the first embodiment. Thereafter, silicon is caused to epitaxially grow on a surface 20c, thereby obtaining a portion of a first semiconductor region 20a1 as illustrated in FIG. 19A. The first semiconductor region 20a1 that is caused to epitaxially grow is, for example, an intrinsic semiconductor (i-type) although the first semiconductor region 20a1 is not limited thereto, and the first semiconductor region 20al may be a p-type or n-type semiconductor in accordance with design. Furthermore, the first semiconductor region 20a1 may be formed to have the same conductivity type as the conductivity type of the second semiconductor region 20a2 or the semiconductor region 21 in accordance with design or may be formed to have a different conductivity type.

Next, silicon is further caused to epitaxially grow, thereby obtaining a remaining part of the first semiconductor region 20a1 as illustrated in FIG. 19B. At that time, silicon is caused to epitaxially grow while known impurities to obtain an n-type semiconductor are injected. In this manner, it is possible to form the n-type first semiconductor region 20a1 and to obtain the formed n type region as the charge accumulation region FD. The following processing is the same as that in the manufacturing method in the second embodiment, and description thereof will thus be omitted. Effects similar to those of the aforementioned light detection device 1 according to the second embodiment are obtained even by the second embodiment.

Furthermore, there is no need to form the resist pattern R5, and it is possible to reduce the lithography process for the light detection device 1 according to the first modification example of the second embodiment.

### Third Modification Example

In a light detection device 1 according to a third modification example of the second embodiment, the shape of an insulating region 26 in longitudinal sectional view is a flat plate shape, which is the same as the shape of the insulating region 26 according to the first embodiment illustrated in FIG. 4F and the like. Effects similar to those of the aforementioned light detection device 1 according to the second embodiment are obtained even by the light detection device 1 according to the third modification example of the second embodiment.

### Third Embodiment

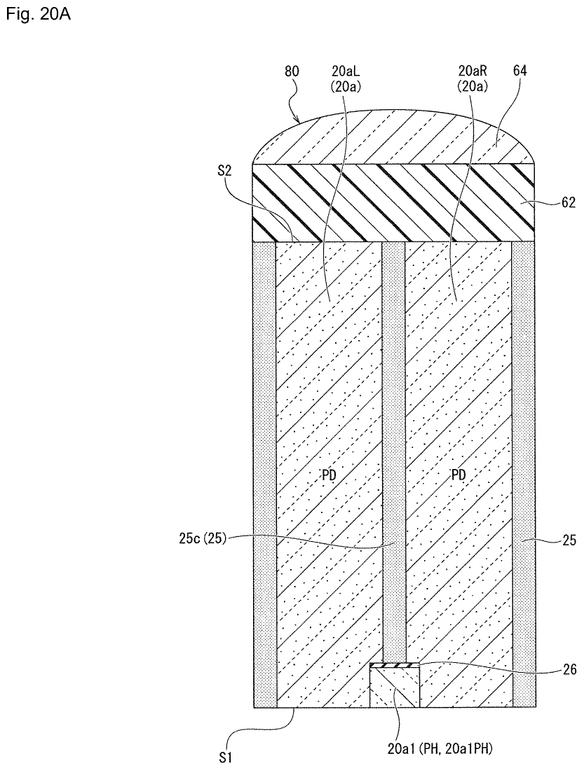

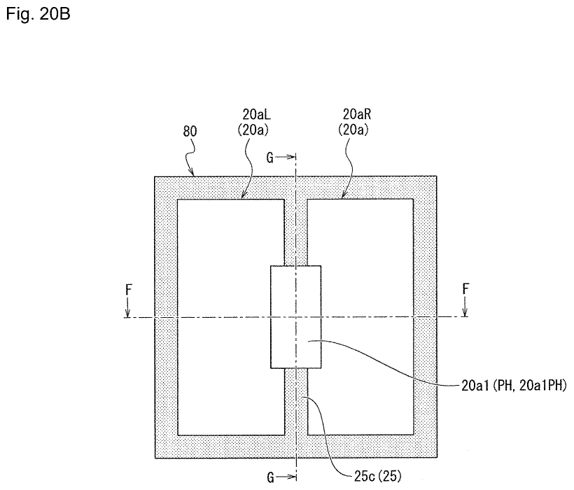

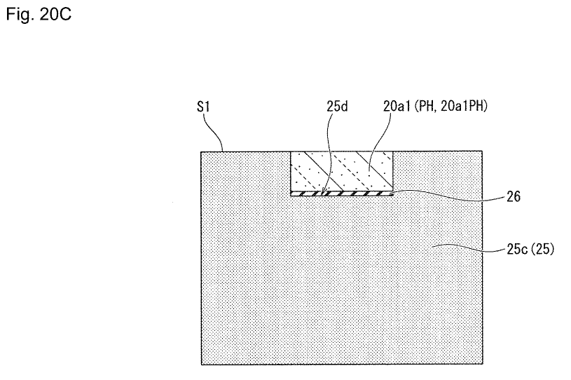

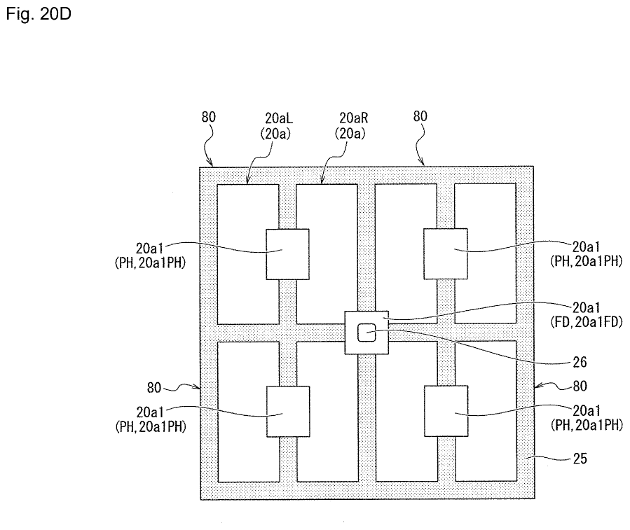

A third embodiment of the present technology illustrated in FIGS. 20A to 20D will be described below. A light detection device 1 according to the present third embodiment includes a phase difference detection unit 80. The other configurations of the light detection device 1 are basically similar to the configurations of the aforementioned light detection device 1 according to the first embodiment. Note that the constituent elements that have already been described will be denoted by the same reference signs and description thereof will be omitted. Note that FIG. 20A is a longitudinal sectional view illustrating a sectional configuration taken along the cut line F-F in FIG. 20B, FIG. 20C is a longitudinal sectional view illustrating a sectional configuration taken along the cut line G-G in FIG. 20B, and FIG. 20B is an explanatory diagram illustrating a positional relationship of constituent elements on a first surface S1.

Note that in the drawings according to the present embodiment, a first semiconductor region 20a1 and a second semiconductor region 20a2 are illustrated in a distinguished manner. Also, conductivity types of semiconductors such as a first conductivity type (a p type, for example), a second conductivity type (an n type, for example), an i type, and the like are illustrated without being distinguished from each other in the drawings according to the present embodiment. In the drawings according to the present embodiment, a first semiconductor layer 20 is focused and is mainly illustrated, and illustration of the other semiconductor layers, wiring layers, and the like may be omitted.

In the drawings according to the present embodiment, some parts of the light detection device 1 are illustrated with illustration of other parts omitted.

Furthermore, in the drawings according to the present embodiment, illustration of electrodes and wirings provided to be in contact with a first semiconductor region 20a1, such as an electrode 70, is omitted for easier understanding of the shape of the first semiconductor region 20a1. Also, although a trench separation wall 25 in the present embodiment is configured to include a polysilicon 25b and an insulating film 25a similarly to the case of the first embodiment, illustration of the insulating film 25a is omitted in the drawings according to the present embodiment.

As illustrated in FIG. 20A, the phase difference detection unit 80 includes a plurality of (two in the present embodiment) adjacent cell regions 20a. Note that in order to distinguish the cell region 20a on the right side in the drawing sheet from the cell region 20a on the left side in the drawing sheet, the cell region on the right side in the drawing sheet will be referred to as a cell region 20aR while the cell region on the left side in the drawing sheet will be referred to as a cell region 20aL. In a case where both the cell regions are not distinguished, the cell regions will be simply referred to as cell regions 20a. The light detection device 1 uses the phase difference detection unit 80 to determine from which direction light has been incident. More specifically, the light detection device 1 compares the amount of signal charge accumulated in the cell region 20aR with the amount of signal charge accumulated in the cell region 20aL to determine from which direction the light has been incident. In a case where the amount of signal charge accumulated in the cell region 20aR is larger than the amount of signal charge accumulated in the cell region 20aL, for example, it is possible to ascertain that light has been incident on the light detection device 1 obliquely from the left side in the drawing sheet.

Also, the phase difference detection unit 80 includes a pathway PH through which a signal charge is movable between the cell region 20aR and the cell region 20aL. The pathway PH may be referred to as an overflow path. In a case where one cell region out of the cell region 20aR and the cell region 20aL is saturated with a signal charge, the signal charge moves from the one cell region to the other cell region via the pathway PH, that is, overflows. The phase difference detection unit 80 can also function as one pixel 3. In a case where the phase difference detection unit 80 also functions as a pixel 3, the phase difference detection unit 80 outputs an addition signal, which is a sum of the amount of signal charge accumulated in the cell region 20aR and the amount of signal charge accumulated in the cell region 20aL, as a pixel signal. Therefore, it is possible to curb a portion of the signal charge being discarded by causing the signal charge to overflow to the other cell region in a case where the one cell region is saturated with the signal charge first. It is thus possible to curb degradation of linearity of the amount of light and the addition signal.

A part of the trench separation wall 25 located between the two cell regions 20a (the cell region 20aR, the cell region 20aL) inside of the phase difference detection unit 80 will be referred to as a first trench separation wall 25c to distinguish it from the other part. In a case where the first trench separation wall 25c and the other trench separation wall 25 are not distinguished from each other, they will be simply referred to as a trench separation wall 25. As illustrated in FIGS. 20A and 20B, the first semiconductor region 20a1 is provided at a position where the first semiconductor region 20a1 overlaps the first trench separation wall 25c in planar view and establishes connection between the cell region 20aR and the cell region 20aL inside of the phase difference detection unit 80. More specifically, the first semiconductor region 20a1 included in the cell region 20aR and the first semiconductor region 20a1 included in the cell region 20aL are connected to each other and are integrated into one component at the position where they overlap the first trench separation wall 25c in planar view. Also, the pathway PH is configured in the first semiconductor region 20a1 provided at the position where the first semiconductor region 20a1 overlaps the first trench separation wall 25c in planar view. It is only necessary for the conductivity type of the first semiconductor region 20a1 where the pathway PH is configured to be a conductivity type in compatible with design.

As illustrated in FIG. 20C, a portion of an end portion of the first trench separation wall 25c on the side of a first surface S1 is depressed in the thickness direction as compared with the other parts, and the insulating region 26 and the first semiconductor region 20a1 are provided only at the depressed part 25d in the end portion of the first trench separation wall 25c.

FIG. 20D illustrates four phase difference detection units 80 aligned in two rows and two columns. The first semiconductor region 20a1 where the charge accumulation region FD is configured is provided at mutually facing corner portions of the four phase difference detection units 80 in planar view. Note that illustration of the electrode 70 is omitted in the present embodiment. The first semiconductor region 20a1 where the charge accumulation region FD is configured has a quadrangular ring shape in planar view and connects the mutually facing corner portions of the four cell regions 20a at the corners of the phase difference detection units 80. Note that in order to distinguish the first semiconductor region 20a1 where the pathway PH is configured from the first semiconductor region 20a1 where the charge accumulation region FD is configured, the first semiconductor region 20a1 where the pathway PH is configured may be referred to as a first semiconductor region 20a1PH, while the first semiconductor region 20a1 where the charge accumulation region FD is configured may be referred to as a first semiconductor region 20a1FD. In a case where both the first semiconductor regions are not distinguished from each other, the first semiconductor regions will be simply referred to as first semiconductor regions 20a1. The first semiconductor region 20a1FD is also provided in the depressed part 25d of the trench separation wall 25 similarly to the first semiconductor region 20a1PH. Moreover, the light detection device 1 may include a contact region 24 with a configuration similar to that of the charge accumulation region FD, and the charge accumulation region FD may be replaced with the contact region 24 in the above description. In a case where the electrode 70 is provided at the first semiconductor region 20a1FD, a trunk portion 71 of the electrode 70 may be formed to have a columnar shape to bury the hollow of the ring-shaped first semiconductor region 20a1FD.

### METHOD OF MANUFACTURING LIGHT DETECTION DEVICE

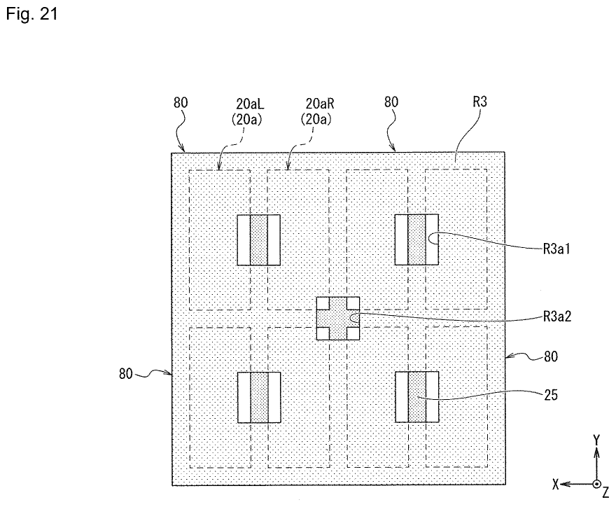

Hereinafter, a method of manufacturing the light detection device 1 will be described with reference to FIGS. 21 to 23. Note that only parts different from those in the aforementioned manufacturing method according to the first embodiment will be described in the present embodiment. Also, the longitudinal sectional views referred to in the following description illustrate a portion of the longitudinal sectional view along the cut line F-F in FIG. 20B. Also, the drawings used to describe the manufacturing method according to the first embodiment will also be referred to in the following description as needed.

The processes up to the one illustrated in FIG. 5A are performed in the same manner as in the aforementioned manufacturing method according to the first embodiment. Thereafter, the groove STI is formed from the side of the first surface S1 such that the groove STI overlaps the trench separation wall 25 in planar view using a known lithography technology and etching technology as illustrated in FIG. 21. At that time, a resist pattern R3 may be formed first, insulating films m1, m2, and m3 may be etched using the resist pattern R3 as a mask, and the groove STI may be formed using the insulating films as hard masks. Note that although the groove STI is formed in a grid shape in planar view in the aforementioned first embodiment, the groove STI is formed only in a rectangular region using the resist pattern R3 having an opening R3a1 and an opening R3a2 in the present embodiment. The opening R3a1 of the resist pattern R3 is provided at a position where the first semiconductor region 20a1PH is formed in planar view, and the opening R3a2 is provided at a position where the first semiconductor region 20a1FD is formed in planar view.

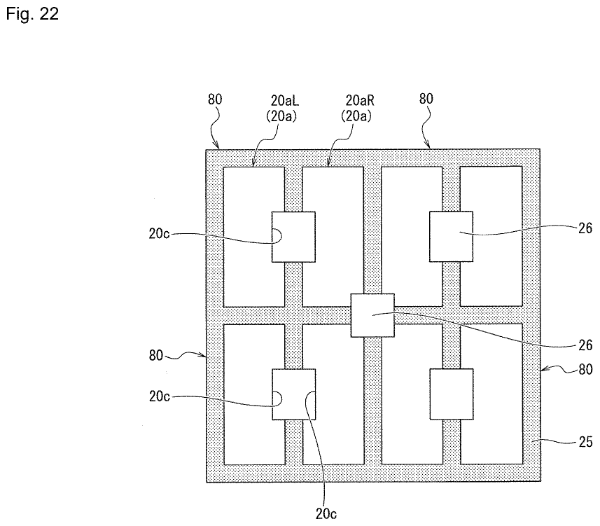

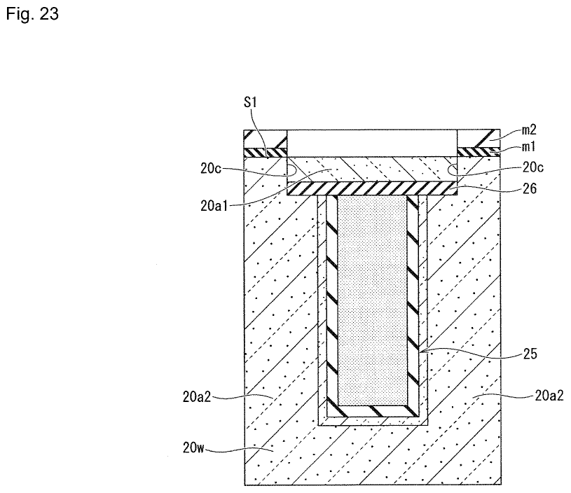

Thereafter, an insulating film m4 is formed to bury the inside of the groove STI as illustrated in FIG. 5C, and etching is performed on the entire surface to remove an unnecessary part of the insulating film m4 as illustrated in FIG. 5D. The insulating film m4 remaining on the bottom portion of the groove STI configures the insulating region 26. FIG. 22 illustrates the shape and the position of the insulating region 26 in planar view. Then, silicon is caused to epitaxially grow on the surface 20c illustrated in FIGS. 5D and 22, thereby obtaining the first semiconductor region 20a1 illustrated in FIG. 23. Note that the surface 20c is a semiconductor surface exposed from the side wall of the groove STI. Note that although the epitaxial growth is controlled to prevent the first semiconductor regions 20a1 that have grown on the facing surfaces 20c from being connected to each other in the aforementioned first embodiment, control is performed to cause the first semiconductor regions 20a1 that have grown on the facing surfaces 20c to be connected to each other as illustrated in FIG. 23 in the present embodiment. In this manner, the cell region 20aR and the cell region 20aL are electrically connected by the first semiconductor region 20a1PH, obtaining the ring-shaped first semiconductor region 20a1FD.

The first semiconductor region 20a1 that has been caused to epitaxially grow is an intrinsic (i-type) semiconductor region, for example, although the first semiconductor region 20a1 is not limited thereto, and the first semiconductor region 20a1 may be a p-type or n type semiconductor region in accordance with design. Furthermore, the first semiconductor region 20a1 may be formed to have the same conductivity type as the conductivity type of the second semiconductor region 20a2 or the semiconductor region 21 in accordance with design or may be formed to have a different conductivity type. The following processing is the same as the processing described in the first embodiment and the known method of manufacturing the phase difference detection unit 80, and description will thus be omitted.

### MAIN EFFECTS OF THIRD EMBODIMENT

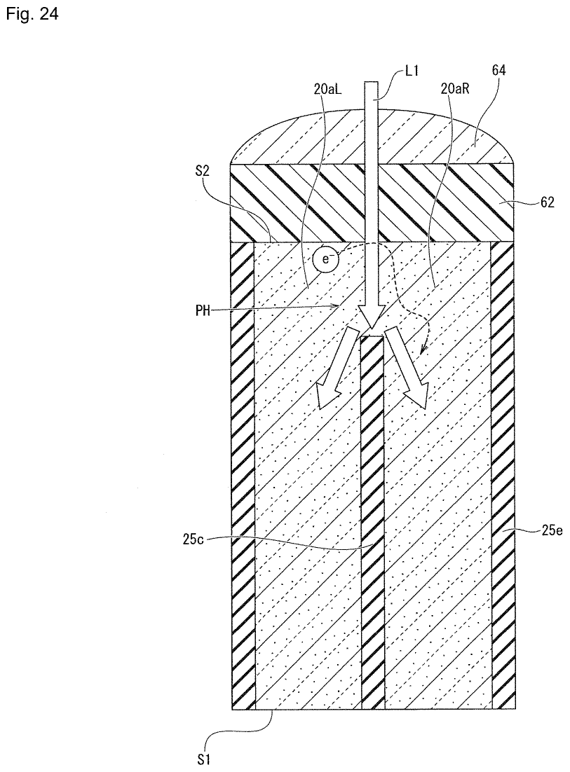

Although main effects of the third embodiment will be described below, refinement of pixels 3 and a comparative example illustrated in FIG. 24 will be described first. It is possible to provide the pathway PH, which is an overflow path, on the side of the first surface S1 in the thickness direction by providing the impurity separation structure between the two cell regions 20a inside of the phase difference detection unit 80. However, further refinement of the pixels has been desired, and it may not be easy to provide the impurity separation structure between the two cell regions 20a in a case where further refinement of the phase difference detection unit 80 is achieved. In that case, separation between the two cell regions 20a by the first trench separation wall 25c is required as illustrated in the comparative example in FIG. 24. Also, the pathway PH, which is an overflow path, may be provided at a position near the color filter 62 in the thickness direction. Therefore, it is necessary to form the height of the first trench separation wall 25c overlapping the pathway PH in planar view to a height that is different from the height of the other trench separation walls 25e, and it may not be easy to perform stable height control. Also, a signal charge generated in one cell region out of the cell region 20aR and the cell region 20aL may move to the other cell region, and the separation property may be degraded. Also, in a case where the first trench separation wall 25c is formed of silicon oxide, incident light L passes the micro-lens 64 and the color filter 62 with low refractive indexes, then passes the pathway PH made of a semiconductor with a high refractive index, and is then incident on the first trench separation wall 25c with a low refractive index again. In that case, the incident light L travels to a low-refractive-index region, a high-refractive-index region, and a low-refractive-index region, and in particular, the light may be reflected or scattered when the light is incident on the first trench separation wall 25c with a low refractive index from the pathway PH in the high-refractive-index region.

On the other hand, the pathway PH is configured in the first semiconductor region 20a1PH provided on the surface of the insulating region 26 on the side opposite to the surface on the side of the first trench separation wall 25c in the light detection device 1 according to the third embodiment of the present technology. In this manner, it is possible to provide the pathway PH at a position near the first surface S1 instead of a position near the second surface S2 even in a case where refinement of the pixels 3 is achieved. Therefore, it is possible to align the position of the end portion of the first trench separation wall 25c on the side of the color filter 62 with the positions of the end portions of the other trench separation walls 25 on the side of the color filter 62 in the thickness direction and to curb degradation of the separation property. Furthermore, since the pathway PH with the high refractive index is not provided on the side of the color filter 62, it is possible to curb an increase in reflection and scattering of the incident light L. Since it is possible to align the position of the end portion of the first trench separation wall 25c on the side of the color filter 62 with the position of the end portions of the other trench separation walls 25 on the side of the color filter 62, it is possible to form all the trench separation walls with the same depth when the first trench separation wall 25c and the other trench separation walls 25 are formed from the side of the first surface S1, and to curb an increase in manufacturing load.

Further, the light detection device 1 according to the third embodiment of the present technology includes the insulating region 26 provided between the end portion of the first trench separation wall 25c near the first surface S1 and the first semiconductor region 20a1PH and made of an insulating material. Since the insulating region 26 intervenes between the first trench separation wall 25c and the first semiconductor region 20a1PH, it is possible to electrically isolate the conductive part of the trench separation wall 25 from the pathway PH in a case where the trench separation wall 25 includes a part made of a conductive body such as polysilicon. Furthermore, it is possible to cause a flow of the signal charge in the pathway PH to concentrate mainly in the horizontal direction. Moreover, it is possible to clarify a concentration difference in impurity concentrations between the first semiconductor region 20a1 and other semiconductor regions such as the photoelectric conversion unit 22, for example, by providing the insulating region 26.

Similarly to the light detection device 1 according to the first embodiment and the light detection device 1 according to the second embodiment described above, it is possible to configure the charge accumulation region FD and the contact region 24 in the region including at least a portion of the first semiconductor region 20a1 in the light detection device 1 according to the third embodiment as well.

Note that the insulating region 26 may be provided in a grid shape in planar view as illustrated in FIG. 4C according to the first embodiment.

### MODIFICATION EXAMPLES OF THIRD EMBODIMENT

Hereinafter, modification examples of the third embodiment will be described.

### First Modification Example

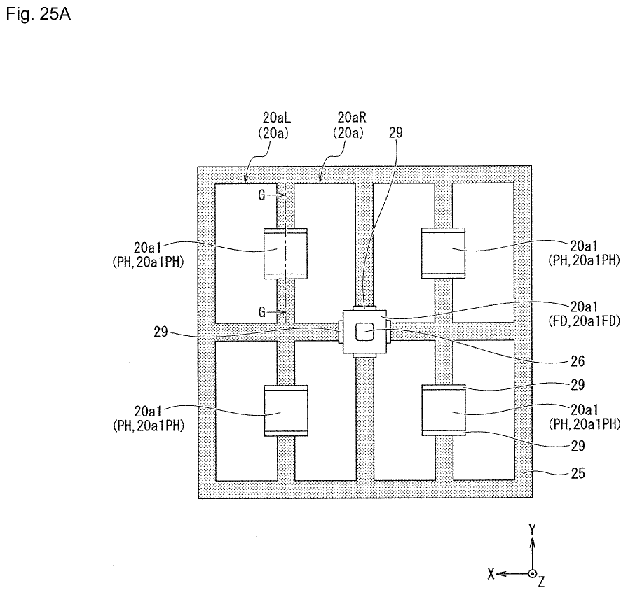

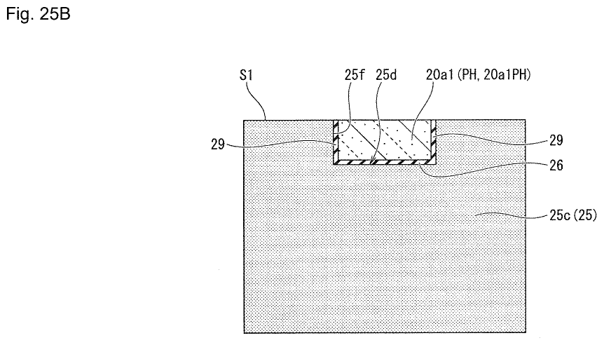

In a light detection device 1 according to a first modification example of the third embodiment illustrated in FIGS. 25A and 25B, an insulating separation region 29 made of an insulating material is provided between a side wall 25f of a depressed part 25d of a first trench separation wall 25c and a first semiconductor region 20a1PH. Also, an insulating separation region 29 made of an insulating material is formed between a side wall 25f of a depressed part 25d of a trench separation wall 25 and a first semiconductor region 20a1FD. The material constituting the insulating separation regions 29 is a known insulating material. The insulating separation region 29 may be configured of the same material as the material configuring an insulating region 26.

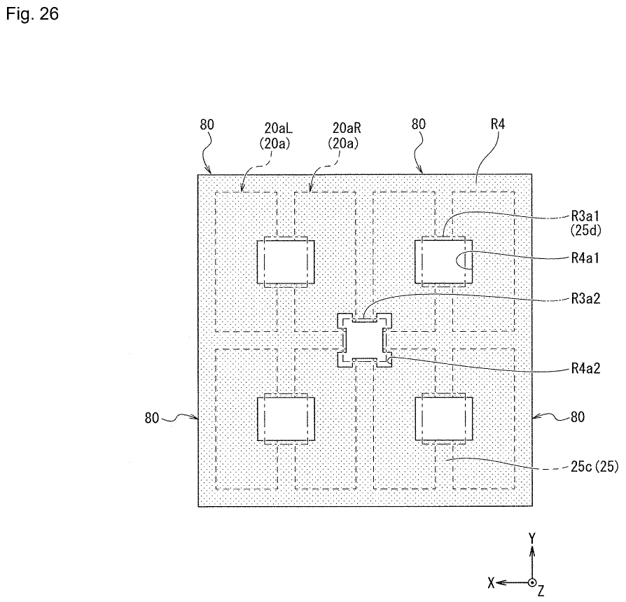

Hereinafter, a method of manufacturing the light detection device 1 will be described with reference to FIG. 26. Note that in this modification example, only parts different from those in the aforementioned manufacturing method according to the third embodiment will be described. More specifically, the manufacturing method according to this modification example is the same as the manufacturing method according to the third embodiment up to the process of forming an insulating film m4 to bury the inside of a groove STI as illustrated in FIG. 5C. Thereafter, an extra part of the insulating film m4 and an insulating film m3 are removed by the CMP method, for example, although illustration is omitted. In this manner, an insulating film m2 is exposed.

Next, a resist pattern R4 having openings R4a1 and R4a2 is formed by the known lithography technology as illustrated in FIG. 26. The opening R4a1 is provided at a position where the first semiconductor region 20a1PH is formed in planar view, and the opening R4a2 is provided at a position where the first semiconductor region 20a1FD is formed in planar view. Then, parts exposed from the openings R4a1 and R4a2 are etched back to remove an unnecessary parts of the insulating film m4, thereby obtaining the insulating region 26. In FIG. 26, the shapes of the openings R4a1 and R4a2 are compared with the shapes of the openings R3a1 and R3a2 of the resist pattern R3 illustrated in FIG. 21.

Note That the sizes of the openings R3a1 and R3a2 are the same as the size of the depressed part 25d of the trench separation wall 25 in planar view. The opening R4a1 has a smaller dimension than the opening R3a1 in a direction along the extending direction (Y direction) of the first trench separation wall 25c. Therefore, both ends of the insulating film m4 buried in the depressed part 25d in the Y direction are covered with the resist and are caused to remain without being etched back. In this manner, it is possible to provide the insulating separation region 29 between the first semiconductor region 20a1 and the side wall 25f of the depressed part 25d of the first trench separation wall 25c. Also, the opening R4a1 has a larger dimension than the opening R3a1 in the direction along the width direction (X direction) of the first trench separation wall 25c, and the insulating film m2 and the insulating film m4 are exposed from the opening R4a1. In the etch back, the insulating film m2 is slightly etched if it is etched, due to a difference in etching rates of the insulating film m2 and the insulating film m4.

The opening R4a2 is provided at a position where the trench separation walls 25 intersect each other in planar view. Therefore, the shape and the dimension of the opening R4a2 are determined such that the insulating film m4 is left at both end portions in both the X direction and the Y direction. Also, since it is necessary to cause silicon to epitaxially grow on the semiconductor surface, the opening R4a2 is widened such that the insulating film m4 is not left on the surface 20c. More specifically, the dimension of the opening R4a2 at the corner portions in the X direction and the Y direction is set to be larger than that of the opening R3a2, and the dimension thereof in the X direction and the Y direction is set to be smaller than that of the opening R3a2 at least in a region with a wider width than the trench separation wall 25 between the corner portions. It is thus possible to provide the insulating separation region 29 between the first semiconductor region 20a1 and the side wall 25f of the depressed part 25d of the first trench separation wall 25c.

Effects similar to those of the aforementioned light detection device 1 according to the third embodiment are obtained even by the light detection device 1 according to the first modification example of the third embodiment. Furthermore, the insulating separation region 29 made of an insulating material is provided between the side wall 25f of the depressed part 25d of the trench separation wall 25 and the first semiconductor region 20a1 in the light detection device 1 according to the first modification example of the third embodiment.

Therefore, it is possible to cause silicon to epitaxially grow in a state where the polysilicon material included in the trench separation wall 25 is covered with the insulating separation region 29 and to cause silicon to grow only on the surface 20c out of the side wall 25f and the surface 20c. In this manner, it is possible to curb abnormal growth of a silicon crystal on the side wall 25f of the trench separation wall 25.

### Second Modification Example

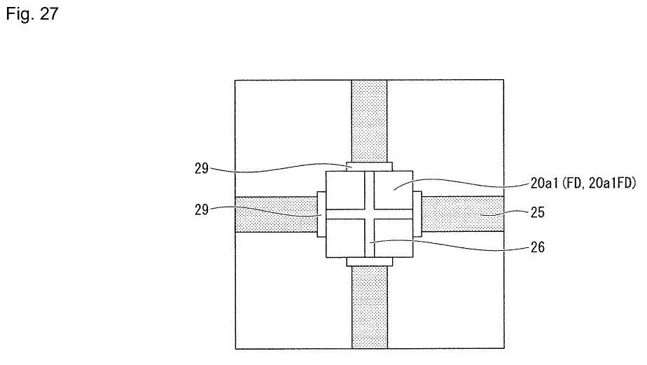

In a light detection device 1 according to a second modification example of the third embodiment illustrated in FIG. 27, a first semiconductor region 20a1FD where a charge accumulation region FD is configured does not have a ring shape, and the first semiconductor region 20a1FD includes four parts provided for each cell region 20a similarly to the case of the first embodiment. Note that the first semiconductor region 20a1FD may be provided with a contact region 24 instead of the charge accumulation region FD.

In order to provide the first semiconductor region 20a1FD separately into four parts, it is only necessary to set the dimension in the X direction and the dimension thereof in the Y direction of the opening R3a2, out of the opening R3a1 and the opening R3a2 of the resist pattern R3 illustrated in FIG. 21 to be larger than the dimension of the opening R3a1 in the X direction (the width direction of the trench separation wall 25). In this manner, it is possible to further elongate the time required by the first semiconductor regions 20a1 that have grown on the facing surfaces 20c to be connected to each other at the position where the first semiconductor region 20a1FD is provided than at the position where the first semiconductor region 20a1PH is provided. In this manner, the first semiconductor region 20a1FD is still in a state where it has not yet been connected at the point at which the one connected first semiconductor region 20a1PH is obtained, and the first semiconductor region 20a1FD illustrated in FIG. 27 is obtained.

Effects similar to those of the aforementioned light detection device 1 according to the third embodiment are obtained even by the light detection device 1 according to the second modification example of the third embodiment.

Furthermore, the electrode 70 with a shape similar to that in the first embodiment can be provided in the light detection device 1 according to the second modification example of the third embodiment.

### Third Modification Example

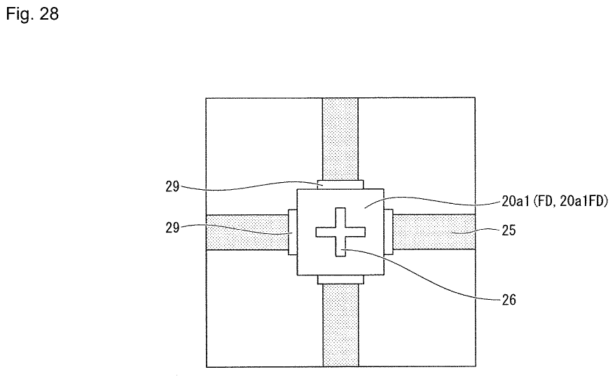

In a light detection device 1 according to a third modification example of the third embodiment illustrated in FIG. 28, first semiconductor region 20a1FD where the charge accumulation region FD is configured may be connected in a ring shape and may include a cross-shaped clearance at the center.

Effects similar to those of the aforementioned light detection device 1 according to the third embodiment are obtained even by the light detection device 1 according to the third modification example of the third embodiment. Furthermore, an electrode 70 with a shape similar to that in the first embodiment can be provided in the light detection device 1 according to the third modification example of the third embodiment.

### Fourth Modification Example

Although a trench separation wall 25 is configured to include polysilicon 25b and an insulating film 25a in the third embodiment, the present technology is not limited thereto. A trench separation wall 25 included in a light detection device 1 according to a fourth modification example of the third embodiment may be configured only of a known insulating film, such as silicon oxide, for example.

Effects similar to those of the aforementioned light detection device 1 according to the third embodiment are obtained even by the light detection device 1 according to the fourth modification example of the third embodiment. In this modification example, the trench separation wall 25 is configured only of silicon oxide with a lower refractive index than a pathway PH, an end portion thereof faces the side of a second surface S2, and a pathway PH with a high refractive index is not provided on the side of a color filter 62. Therefore, in a case where light passing a micro-lens 64, the color filter 62, and the trench separation wall 25 in this order is considered, the light passes the micro-lens 64 and the color filter 62 with lower refractive indexes than the pathway PH and is then incident directly on the trench separation wall 25 without intervention of a region with a high refractive index. In this manner, the light is incident from a low-refractive-index region to a low-refractive index region, and it is thus possible to curb reflection and scattering of light when the light is incident on the trench separation wall 25.

### Fourth Embodiment

### 1. Example of Application to Electronic Device

Next, an electronic device 100 according to a fourth embodiment of the present technology illustrated in FIG. 29 will be described. The electronic device 100 includes a solid-state imaging device 101, an optical lens 102, a shutter device 103, a drive circuit 104, and a signal processing circuit 105. Although not limited thereto, the electronic device 100 is an electronic device such as a camera, for example. The electronic device 100 includes the light detection device 1 described above as the solid-state imaging device 101.

The optical lens (optical system) 102 forms an image of image light (incident light 106) from the subject on an imaging surface of the solid-state imaging device 101. As a result, signal charges are accumulated within the solid-state imaging device 101 for a certain period of time. The shutter device 103 controls a light irradiation period and a light blocking period of the solid-state imaging device 101. The drive circuit 104 supplies drive signals that control a transfer operation of the solid-state imaging device 101 and a shutter operation of the shutter device 103. Signal transfer of the solid-state imaging device 101 is performed by a drive signal (timing signal) supplied from the drive circuit 104. The signal processing circuit 105 performs various types of signal processing on signals (pixel signals) output from the solid-state imaging device 101. A video signal having been subjected to signal processing is stored in a storage medium such as a memory or is output to a monitor.

With such a configuration, the electronic device 100 includes the first semiconductor region 20a1 provided on the surface of the insulating region 26 on the side opposite to the surface on the side of the trench separation wall 25 in the solid-state imaging device 101, and it is thus possible to improve image quality of the video signal.

Note that the electronic device 100 is not limited to a camera and may be another electronic device. For example, the electronic device 100 may be an imaging device such as a camera module for a mobile device such as a mobile phone.

Also, the electronic device 100 can include, as the solid-state imaging device 101, the light detection device 1 according to any of the first to third embodiments and the modification examples of these embodiments and a light detection device 1 according to a combination of at least two of the first to third embodiments and the modification examples of these embodiments.

### Other Embodiments

As described above, while the present technology has been described with reference to the first to fourth embodiments, the description and the drawings forming a part of the present disclosure should not be construed as limiting the present technology. Various alternative embodiments, working examples, and operational techniques should be clear to a person skilled in the art on the basis of the disclosure.

For example, technical ideas described in the first to fourth embodiments can be combined together. Although the aforementioned light detection device 1 according to the sixth modification example of the first embodiment includes only two semiconductor layers, for example, such a technical idea can be applied to the light detection devices 1 described in the second embodiment and the third embodiment. Also, although the aforementioned light detection device 1 according to the third embodiment includes the phase difference detection unit 80, for example, such a technical idea can be applied to the light detection devices 1 described in the first embodiment and the second embodiment, and various combinations based on each technical idea can be made.

The present technology can be generally applied to a light detection device including a range sensor to measure the distance, which is also called a time-of-flight (ToF) sensor, as well as the aforementioned solid-state imaging device as an image sensor. The range sensor is a sensor that emits irradiation light toward an object, detects reflected light of the irradiation light which is reflected by and returns from the surface of the object, and calculates the distance to the object on the basis of a flight time until the reflected light is received after the irradiation light is emitted. As a structure of the range sensor, it is possible to employ the aforementioned structure of the pixels 3.

In addition, the aforementioned materials listed as constituting the constituent elements may include additives and impurities, for example.

In this manner, it goes without saying that the present technology includes various embodiments and the like not described herein. Accordingly, the technical scope of the present technology is to be defined only by the inventive specific matters described in the claims pursuant to the above descriptions.

Furthermore, the effects described in the present specification are merely exemplary and not intended to be limiting, and other effects may be provided as well.

The present technology may be configured as follows.
(1)

A light detection device including:
a first semiconductor layer that includes one surface as an element formation surface and the other surface as a light incident surface and includes a plurality of cell regions aligned in a matrix shape in a row direction and a column direction in planar view;
a trench separation wall that sections the cell regions; and
an insulating region that is provided at an end portion of the trench separation wall near the element formation surface, has a dimension in a width direction that is larger than a dimension of the trench separation wall in the width direction in planar view, and is made of an insulating material,
in which a photoelectric conversion unit is configured in each of the cell regions, and
each of the cell regions includes a first semiconductor region provided on a surface of the insulating region on a side opposite to a surface on a side of the trench separation wall.
(2)

The light detection device according to (1), including:
an electrode that includes a trunk portion and a head portion that has one surface connected to one end portion of the trunk portion,
in which a charge accumulation region is configured in a region of each of the cell regions including at least a portion of the first semiconductor region,
the other end portion of the trunk portion is in contact with a surface of the insulating region near the element formation surface, and
the electrode is in contact with the charge accumulation region via a side surface of the trunk portion and the one surface of the head portion.
(3)

The light detection device according to (2), in which the side surface of the trunk portion and the one surface of the head portion are in contact with the first semiconductor region where the charge accumulation region is configured.
(4)

The light detection device according to (2) or (3), in which the electrode is in contact with each of a plurality of the charge accumulation regions provided in the different cell regions.
(5)

The light detection device according to (4), in which in a case where a distance between two of the charge accumulation regions facing via the trunk portion in a longitudinal sectional view is defined as b and a dimension of the insulating region in a horizontal direction is defined as a, a relationship of b <a is satisfied.
(6)

The light detection device according to (5), in which in a case where a dimension of the head portion in the horizontal direction is defined as c in the longitudinal sectional view, a relationship of b≤c is satisfied.
(7)

The light detection device according to any of (4) to (6),
in which in four of the cell regions in two rows and two columns, the charge accumulation regions are provided at mutually facing corners of the cell regions in planar view,
the trunk portion includes a first extending part that extends in a row direction and a thickness direction and a second extending part that extends in a column direction and the thickness direction and intersects the first extending part in planar view, and the charge accumulation regions are in contact with the trunk portion at recessed corner portions configured by the first extending part and the second extending part.
(8)

The light detection device according to any of (2) to (7), including:
a contact electrode that includes a contact trunk portion and a contact head portion that has one surface connected to one end portion of the contact trunk portion,
in which a contact region fixed to a reference potential via the contact electrode is configured in a region of each of the cell regions including at least a portion of the first semiconductor region,
the other end portion of the contact trunk portion is in contact with the surface of the insulating region near the element formation surface, and
the contact electrode is in contact with the contact region via a side surface of the contact trunk portion and the one surface of the contact head portion.
(9)

The light detection device according to any of (2) to (8), in which the insulating region is provided over an entire location where the trench separation wall is provided in planar view.
(10)

The light detection device according to any of (2) to (9), in which the first semiconductor region is provided over an entire edge portion of each of the cell regions on the element formation surface.
(11)

The light detection device according to any of (2) to (9), in which the first semiconductor region is provided only at a corner portion of each of the cell regions on the element formation surface.
(12)

The light detection device according to any of (2) to (11), in which each of the charge accumulation regions is configured of a region of each of the cell regions including only the first semiconductor region, and the entire charge accumulation region overlaps the insulating region in planar view.
(13)

The light detection device according to (12), in which in a case where a distance between two of the charge accumulation regions facing each other via the trunk portion in a longitudinal sectional view is defined as b, a dimension of the head portion in the horizontal direction is defined as c, and a dimension of each of the
(14)

The light detection device according to (12) or (13), in which a width occupied by two of the charge accumulation regions facing each other via the trunk portion in a horizontal direction in a longitudinal sectional view is equal to or less than a dimension of the insulating region in the horizontal direction in the sectional view.
(15)

The light detection device according to (1), including:
a phase difference detection unit that includes two of the adjacent cell regions and a pathway through which a signal charge is movable between the two adjacent cell regions,
in which in a case where a part of the trench separation wall located between the two cell regions in the phase difference detection unit is defined as a first trench separation wall, the first semiconductor region is provided at a location where the first semiconductor region overlaps the first trench separation wall in planar view and connects the two cell regions in the phase difference detection unit, and
the pathway is configured in the first semiconductor region.
(16)

The light detection device according to (15),
in which an end portion of the first trench separation wall on a side of the element formation surface has a part depressed in a thickness direction as compared with the other part, and
the insulating region and the first semiconductor region are provided only at the depressed part of the end portion.
(17)

The light detection device according to (16), in which an insulating separation region made of an insulating material is provided between a side wall at the depressed part of the first trench separation wall and the first semiconductor region.
(18)

The light detection device according to any of (2) to (8) and (12) to (17), in which an end portion of the trench separation wall on the side of the element formation surface has a part depressed in a thickness direction as compared with the other part,
the insulating region and the first semiconductor region are provided only at the depressed part of the end portion, and
the charge accumulation region or a contact region fixed to a reference potential is configured in the first semiconductor region.
(19)

The light detection device according to (18), in which an insulating separation region made of an insulating material is provided between a side wall of the depressed part of the trench separation wall and the first semiconductor region.
(20) An electronic device including:
a light detection device; and
an optical system that forms an image of image light from a subject on the light detection device,
in which the light detection device includes a first semiconductor layer that includes one surface as an element formation surface and the other surface as a light incident surface and includes a plurality of cell regions aligned in a matrix shape in a row direction and a column direction in planar view;
a trench separation wall that sections the cell regions; and
an insulating region that is provided at an end portion of the trench separation wall near the element formation surface, has a dimension in a width direction that is larger than a dimension of the trench separation wall in the width direction in planar view, and is made of an insulating material,
in which a photoelectric conversion unit is configured in each of the cell regions, and
each of the cell regions includes a first semiconductor region provided on a surface of the insulating region on a side opposite to a surface on a side of the trench separation wall.

The scope of the present technology is not limited to the illustrated and described exemplary embodiments, but includes all embodiments that provide equivalent effects sought after with the present technology. Furthermore, the scope of the present technology is not limited to combinations of characteristics of the invention defined by the claims, but can be defined by any desired combinations of specific characteristics among all the disclosed characteristics.

### REFERENCE SIGNS LIST

1 Light detection device
20 First semiconductor layer
20a, 20aL, 20aR Cell region
20a1, 20a1FD, 20a1PH First semiconductor region
20b Separation region
24 Contact region (semiconductor region)
25 Trench separation wall
25c First trench separation wall
25d Depressed part
70 Electrode
70 Contact electrode
71 Trunk portion
71 Contact trunk portion
71x First extending part
71y Second extending part
72 Head portion
72 Contact head portion
80 Phase difference detection unit
100 Electronic device
102 Optical system
a Dimension
b Distance
c Dimension
d Dimension
FD Charge accumulation region
PH Pathway
W1, W2 Dimension

1. A light detection device comprising:
a first semiconductor layer that includes one surface as an element formation surface and the other surface as a light incident surface and includes a plurality of cell regions aligned in a matrix shape in a row direction and a column direction in planar view;
a trench separation wall that sections the cell regions; and
an insulating region that is provided at an end portion of the trench separation wall near the element formation surface, has a dimension in a width direction that is larger than a dimension of the trench separation wall in the width direction in planar view, and is made of an insulating material,
wherein a photoelectric conversion unit is configured in each of the cell regions, and
each of the cell regions includes a first semiconductor region provided on a surface of the insulating region on a side opposite to a surface on a side of the trench separation wall.

2. The light detection device according to claim 1, comprising:
an electrode that includes a trunk portion and a head portion that has one surface connected to one end portion of the trunk portion,
wherein a charge accumulation region is configured in a region of each of the cell regions including at least a portion of the first semiconductor region, the other end portion of the trunk portion is in contact with a surface of the insulating region near the element formation surface, and
the electrode is in contact with the charge accumulation region via a side surface of the trunk portion and the one surface of the head portion.

3. The light detection device according to claim 2, wherein the side surface of the trunk portion and the one surface of the head portion are in contact with the first semiconductor region where the charge accumulation region is configured.

4. The light detection device according to claim 2, wherein the electrode is in contact with each of a plurality of the charge accumulation regions provided in the different cell regions.

5. The light detection device according to claim 4, wherein in a case where a distance between two of the charge accumulation regions facing via the trunk portion in a longitudinal sectional view is defined as b and a dimension of the insulating region in a horizontal direction is defined as a, a relationship of b<a is satisfied.

6. The light detection device according to claim 5, wherein in a case where a dimension of the head portion in the horizontal direction is defined as c in the longitudinal sectional view, a relationship of b ≤c is satisfied.

7. The light detection device according to claim 4,
wherein in four of the cell regions in two rows and two columns, the charge accumulation regions are provided at mutually facing corners of the cell regions in planar view,
the trunk portion includes a first extending part that extends in a row direction and a thickness direction and a second extending part that extends in a column direction and the thickness direction and intersects the first extending part in planar view, and
the charge accumulation regions are in contact with the trunk portion at recessed corner portions configured by the first extending part and the second extending part.

8. The light detection device according to claim 2, comprising:
a contact electrode that includes a contact trunk portion and a contact head portion that has one surface connected to one end portion of the contact trunk portion,
wherein a contact region fixed to a reference potential via the contact electrode is configured in a region of each of the cell regions including at least a portion of the first semiconductor region,
the other end portion of the contact trunk portion is in contact with the surface of the insulating region near the element formation surface, and
the contact electrode is in contact with the contact region via a side surface of the contact trunk portion and the one surface of the contact head portion.

9. The light detection device according to claim 2, wherein the insulating region is provided over an entire location where the trench separation wall is provided in planar view.

10. The light detection device according to claim 2, wherein the first semiconductor region is provided over an entire edge portion of each of the cell regions on the element formation surface.

11. The light detection device according to claim 2, wherein the first semiconductor region is provided only at a corner portion of each of the cell regions on the element formation surface.

12. The light detection device according to claim 2, wherein each of the charge accumulation regions is configured of a region of each of the cell regions including only the first semiconductor region, and the entire charge accumulation region overlaps the insulating region in planar view.

13. The light detection device according to claim 12, wherein in a case where a distance between two of the charge accumulation regions facing each other via the trunk portion in a longitudinal sectional view is defined as b, a dimension of the head portion in the horizontal direction is defined as c, and a dimension of each of the charge accumulation regions in the horizontal direction is defined as d, a relationship of c≥2d+b is satisfied.

14. The light detection device according to claim 12, wherein a width occupied by two of the charge accumulation regions facing each other via the trunk portion in a horizontal direction in a longitudinal sectional view is equal to or less than a dimension of the insulating region in the horizontal direction in the sectional view.

15. The light detection device according to claim 1, comprising:
a phase difference detection unit that includes two of the adjacent cell regions and a pathway through which a signal charge is movable between the two adjacent cell regions,
wherein in a case where a part of the trench separation wall located between the two cell regions in the phase difference detection unit is defined as a first trench separation wall, the first semiconductor region is provided at a location where the first semiconductor region overlaps the first trench separation wall in planar view and connects the two cell regions in the phase difference detection unit, and
the pathway is configured in the first semiconductor region.

16. The light detection device according to claim 15,
wherein an end portion of the first trench separation wall on a side of the element formation surface has a part depressed in a thickness direction as compared with the other part, and
the insulating region and the first semiconductor region are provided only at the depressed part of the end portion.

17. The light detection device according to claim 16, wherein an insulating separation region made of an insulating material is provided between a side wall at the depressed part of the first trench separation wall and the first semiconductor region.

18. The light detection device according to claim 2,
wherein an end portion of the trench separation wall on the side of the element formation surface has a part depressed in a thickness direction as compared with the other part,
the insulating region and the first semiconductor region are provided only at the depressed part of the end portion, and
the charge accumulation region or a contact region fixed to a reference potential is configured in the first semiconductor region.

19. The light detection device according to claim 18, wherein an insulating separation region made of an insulating material is provided between a side wall of the depressed part of the trench separation wall and the first semiconductor region.

20. An electronic device comprising:
a light detection device; and
an optical system that forms an image of image light from a subject on the light detection device,
wherein the light detection device includes
a first semiconductor layer that includes one surface as an element formation surface and the other surface as a light incident surface and includes a plurality of cell regions aligned in a matrix shape in a row direction and a column direction in planar view;
a trench separation wall that sections the cell regions; and
an insulating region that is provided at an end portion of the trench separation wall near the element formation surface, has a dimension in a width direction that is larger than a dimension of the trench separation wall in the width direction in planar view, and is made of an insulating material,
wherein a photoelectric conversion unit is configured in each of the cell regions, and
each of the cell regions includes a first semiconductor region provided on a surface of the insulating region on a side opposite to a surface on a side of the trench separation wall.
